(19) United States
(12) Patent Application Publication
(10) Pub. No.: US 2025/0275318 A1
(43) Pub. Date: Aug. 28, 2025

(54) HIGH EFFICIENT LED PIXEL ARRAY WITH OPTIMIZED N-CONTACT DESIGN

(71) Applicant: Lumileds LLC, San Joase, CA (US)

(72) Inventors: Toni Lopez, Vaals (NL); Erik William Young, San Jose, CA (US)

(73) Assignee: Lumileds LLC, San Jose, CA (US)

(21) Appl. No.: 18/585,457

(22) Filed: Feb. 23, 2024

(51) Int. Cl. H01L 33/62; H01L 27/15; H01L 33/00; H01L 33/20; H01L 33/50

(52) U.S. Cl. CPC H10H 20/857; H10H 20/81; H10H 20/819; H10H 20/851; H10H 29/142

(57) ABSTRACT

Arrays of light emitting diode (LED) devices, each LED device includes a mesa having a top surface and at least one sidewall defining a trench having a bottom surface. The mesa comprises semiconductor layers including an N-type layer, an active layer, and a P-type layer, and an electrically conductive material fills the trench. A dielectric layer lines the trench such that the dielectric layer optically isolates the electrically conductive material the trench.

### TECHNICAL FIELD

Embodiments of the disclosure generally relate to arrays of light emitting diode (LED) devices and methods of manufacturing the same. More particularly, embodiments are directed to arrays of light emitting diode devices and methods of manufacture in which n-contact formation is provided at the mesa bottom over a limited region around the periphery of the pixel.

### BACKGROUND

A light emitting diode (LED) is a semiconductor light source that emits visible light when current flows through it. LEDs combine a P-type semiconductor with an N-type semiconductor. LEDs commonly use a III-V group compound semiconductor. A III-V group compound semiconductor provides stable operation at a higher temperature than devices that use other semiconductors. The III-V group compound is typically formed on a substrate formed of sapphire, silicon (Si), or silicon carbide (SiC).

In-organic light emitting diodes (i-LEDs) have been widely used to create different types of displays, LED matrices and light engines including automotive adaptive headlights, augmented-, virtual-, mix-reality (AR/VR/MR) headsets, smart glasses and displays for mobile phones, smart watches, monitors and TVs. The individual LED pixels in these architectures could have an area of few square millimetres down to few square micrometres depending on the matrix or display size and its pixel per inch requirements. One common approach is to create a monolithic array of LED pixels on an EPI wafer and later transfer and hybridize these LED arrays to a backplane to control individual pixels.

One embodiment of such monolithic arrays uses metal (e.g., Al- or Ag-based) side-contacts. These side-contacts serve as the electrical cathode for each pixel and also provide reflective sidewalls in between the pixels to reduce light scattering and propagation in lateral directions. An example of such LED arrays is shown in FIGS. 1-2. As shown in these figures, with this geometry a metal grid is created in between pixels of an LED display or matrix. These aluminum or silver side-contacts 16 are typically extended deep into the bottom of the trench 12 in between the pixels formed by etching and/or segmenting the semiconductor (epitaxial) layers and reach the substrate's surface. Deep side contacts 16 can be used to ensure low sheet and contact resistance for cathode contacts, and to optically separate each LED pixel so that there is no optical crosstalk, thereby maximize optical contrast. There is, however, a cost of optical absorption due to the limited reflectivity of the metal contact. For example, since the trench 12 surface interface to the epitaxial layers (e.g., n-type layers 14, active region 13, p-type layers 15) must be a metal to form contact, optical efficiency (e.g., package efficiency, PE and extraction efficiency, ExE) can be limited by severe absorption in the cavity since metals are usually poor optical reflectors. A p-metal layer 17 may be formed on the p-type layers 15.

In many of these architectures, the substrate (e.g., sapphire, silicon) is removed after the LED array is integrated with the backplane controller to enhance light extraction and beam profiling. A standard approach to remove a sapphire substrate is by a laser lift-off process where a laser beam (UV laser in the case of a sapphire substrate) is used to detach the substrate from the epitaxial layers (e.g., n-type layers 14, active region 13, p-type layers 15, in this case, LED arrays grown on the substrate). Such methods could damage the side contacts, and such effects could also pose long-term reliability concerns.

Accordingly, there is a need for monolithic LED arrays and improved fabrication processes that improve optical efficiency.

### SUMMARY

Embodiments of the disclosure are directed to a light emitting diode (LED) device. In one or more embodiments, a LED device comprises: at least one mesa comprising semiconductor layers, the semiconductor layers including an n-type layer, an active layer, and a p-type layer, the at least one mesa having a top surface and sidewalls, at least one sidewall defining a trench having a bottom surface; a dielectric layer disposed on at least portions of the sidewalls; an electrically conductive material disposed in the trench and in contact with the dielectric layer; and a p-type contact on the top surface of the mesa, wherein the dielectric layer extends between the semiconductor layers and the electrically conductive material along at least a portion of the trench opposing sidewalls, wherein at least a portion of the electrically conductive material is in direct contact with at least a portion of the bottom surface of the trench and/or at least a portion of the n-type layer, and wherein the dielectric layer optically isolates the trench.

Another aspect of the disclosure pertains to a light emitting diode (LED) array. In one or more embodiments, an LED array comprises: a plurality of mesas defining pixels, each of the mesas comprising semiconductor layers, the semiconductor layers including an n-type layer, an active layer, and a p-type layer, each of the mesas having a top surface and sidewalls; a plurality of trenches, each of the trenches disposed between each of the mesas, each of the trenches having a bottom surface and opposing side surfaces defining the sidewalls of the mesas, at least one trench having a lower narrower portion and an upper wider portion, the upper wider portion further comprising opposing horizontal surfaces; an electrically conductive material disposed in each of the trenches; a dielectric layer disposed on at least portions of the sidewalls; an electrically conductive material disposed in the trench and in contact with the dielectric layer; and a p-type contact on the top surface of at least one mesa, wherein at least a portion of the electrically conductive material is in direct contact with at least a portion of the bottom surface of at least one trench and/or at least a portion of the n-type layer in at least one trench, and wherein the dielectric layer optically isolates the trenches.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a perspective view of a conventional LED pixel with full metal trench sidewalls according to the prior art;

FIG. 2 illustrates a cross-sectional view of the LED pixel of FIG. 1 according to the prior art;

FIGS. 3A-3K illustrate cross-sectional views of a portion of an LED device during a method of manufacture according to one or more embodiments, the LED device having self-aligned N-contact without bottom dielectric coverage;

FIG. 4A illustrates a bottom schematic view of a pixel LED die fabricated according to FIGS. 3A-3K, with self-aligned n-contact formation at the pixel corners according to one or more embodiments;

FIG. 4B illustrates a perspective view of a pixel LED die with self-aligned n-contact formation at the pixel corners taken along the dashed line of FIG. 4A;

FIGS. 5A-5F illustrate cross-sectional views of a portion of an LED device during a method of manufacture according to one or more embodiments;

FIGS. 6A-6B illustrate bottom schematic views of embodiments of pixel LED die fabricated according to FIGS. 5A-5F;

FIG. 6C illustrates a perspective view of a pixel LED die with taken along the dashed line of FIGS. 6A-6B;

FIGS. 7A-7G illustrate cross-sectional views of a portion of an LED device during a method of manufacture according to one or more embodiments;

FIG. 8A illustrates a bottom schematic view of an array of pixel LED die fabricated according to FIGS. 7A-7G according to one or more embodiments;

FIG. 8B illustrates a perspective view of a pixel LED die taken along the dashed line of FIG. 8A;

FIG. 9 illustrates a process flow diagram for a method of manufacturing an LED device according to one or more embodiments;

FIG. 10 illustrates a process flow diagram for a method of manufacturing an LED device according to one or more embodiments;

FIG. 11 illustrates a process flow diagram for a method of manufacturing an LED device according to one or more embodiments;

FIG. 12 illustrates a top plan view of an exemplary display device according to one or more embodiments; and

FIG. 13 schematically illustrates an exemplary display system comprising LED devices according to embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN and alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Reference to a micro-LED (uLED) means a light emitting diode having one or more characteristic dimensions (e.g., height, width, depth, thickness, etc. dimensions) of less than 100 micrometers. In one or embodiments, one or more dimensions of height, width, depth, thickness have values in a range of 1 to 100 micrometers, including all values and subranges therebetween.

LEDs capable of operation across the visible spectrum include Group III-V semiconductors, particularly binary, ternary, and quaternary alloys of gallium, aluminum, indium, and nitrogen, also referred to as III-nitride materials. Typically, Ill-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

The disclosure provides a die/epi/converter layout for creating monolithic micro-LED arrays, Mini-LEDs, and LED arrays with increased optical performance. The materials and structure provide significant improvements in the optical performance of state-of-the-art monolithically integrated micro-LED or LED arrays. The methods and devices are applicable to both phosphor-converted and direct-color LEDs where each individual pixel has an area ranging from few hundred square micrometres (Micro-LEDs) to square millimetres (conventional LEDs).

Embodiments herein describe LED devices and methods for forming LED devices. In particular, the present disclosure describes arrays of LED devices in which the n-contact area is reduced. According to embodiments of the disclosure, pixels are formed with full trenches of composite materials that enable both low optical absorption and optical isolation across near neighbouring pixels. Embodiments of the disclosure offer significant advantages in optical efficacy (Im/W).

The embodiments of the disclosure are described by way of the Figures, which illustrate devices (e.g., LEDs) and processes for forming devices in accordance with one or more embodiments of the disclosure. The processes shown are merely illustrative possible uses for the disclosed processes, and the skilled artisan will recognize that the disclosed processes are not limited to the illustrated applications.

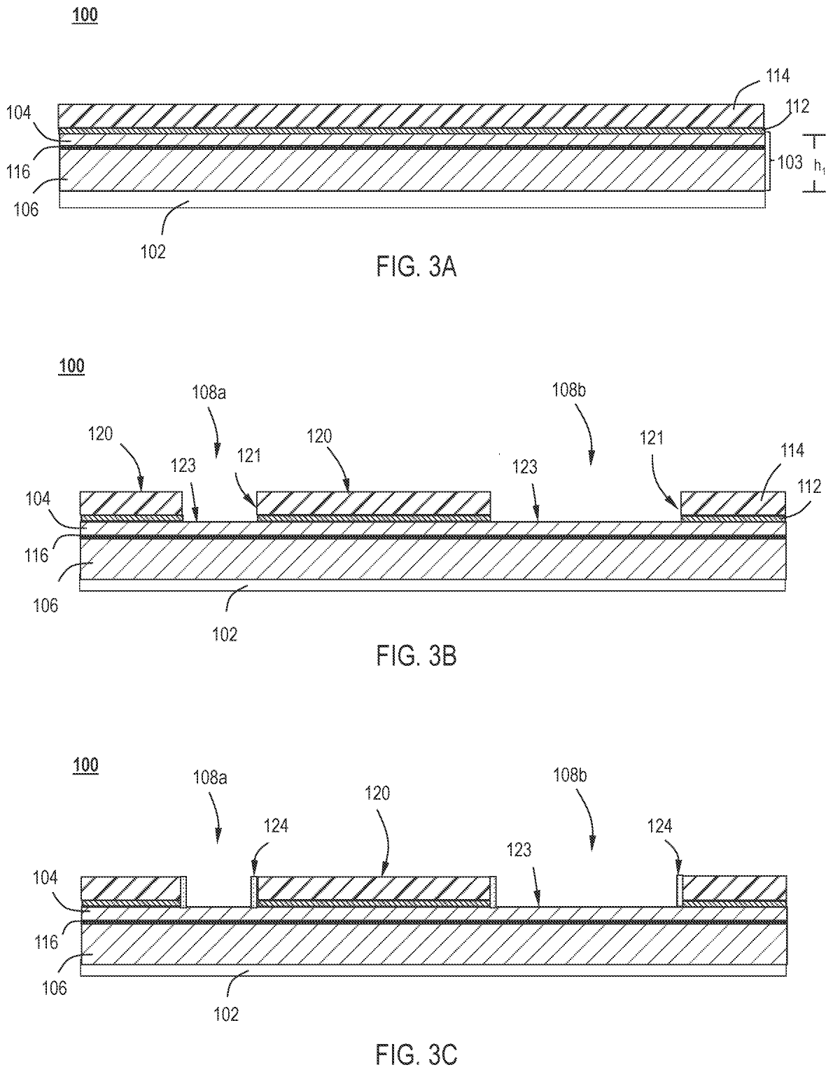

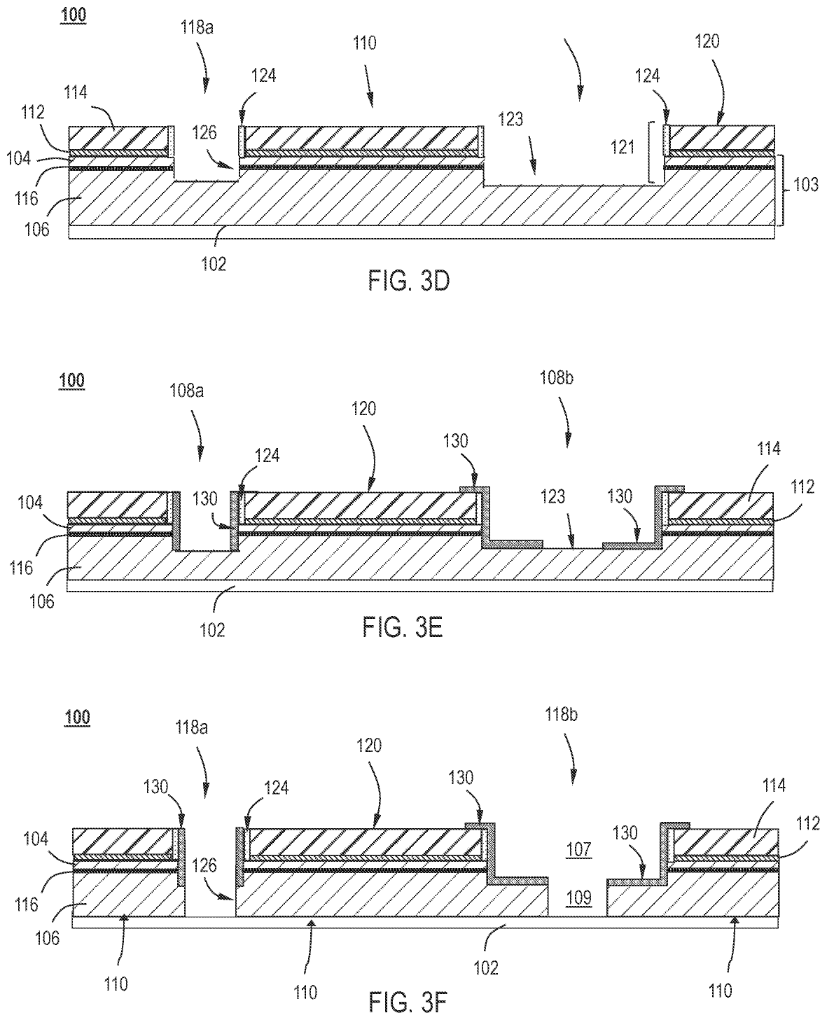

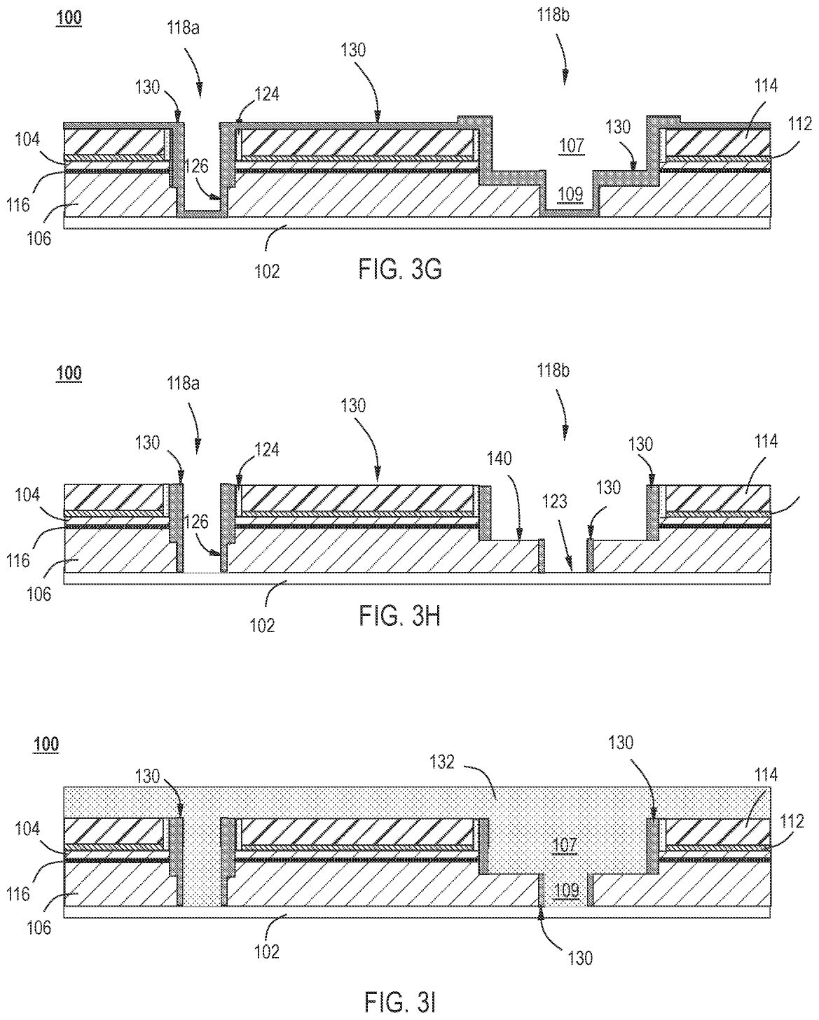

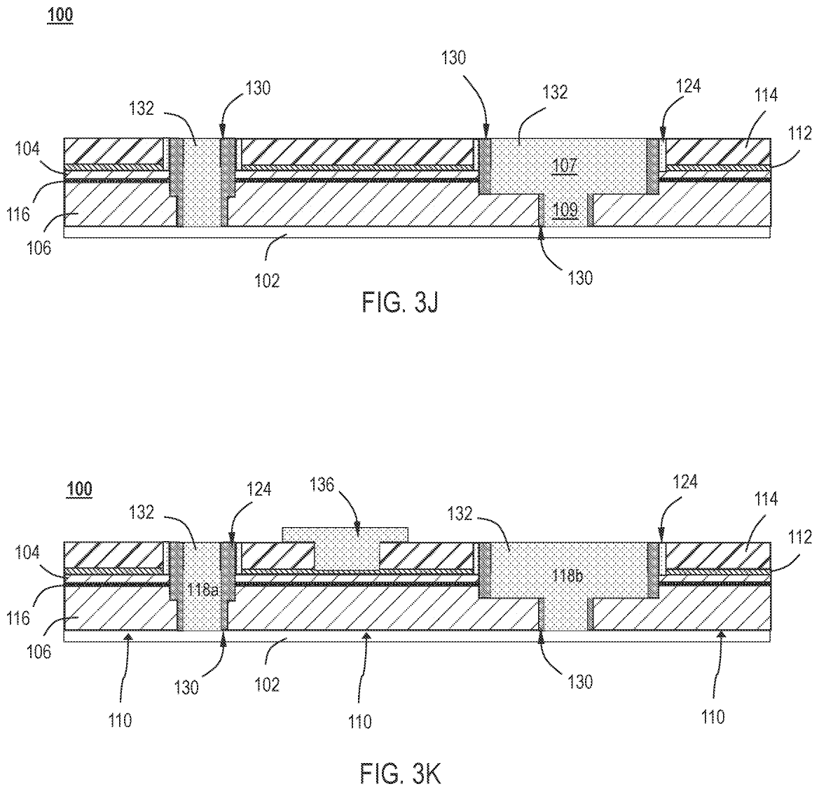

As illustrated in FIGS. 3F-3K, 5A-5F, and 7E-71, the device 100, 200, 300 includes a plurality of mesas 110, 210, 310 comprising semiconductor layers 103, 203, 303 having a total height h₁. As shown, the semiconductor layers 103, 203, 303 including an n-type layer 106, 206, 306 an active region 116, 216, 316 and a p-type layer 104, 204, 304. As illustrated, the semiconductor layers 103, 203, 303 are disposed on a substrate 102, 202, 302 (which can subsequently be removed as further described herein), with the n-type layer 106, 206, 306 disposed on the substrate surface, the active region 116, 216, 316 disposed on the n-type layer 106, 206, 306, and the p-type layer 104, 204, 304 disposed on the active region 116, 216, 316. In one or more embodiments, the semiconductor layers 103, 203, 303 may be patterned or unpatterned. In the embodiments illustrated, the semiconductor layers 103, 203, 303 are unpatterned. One of skill in the art, however, recognizes that the semiconductor layers 103, 203, 303 may be patterned, as the n-type layer 14 illustrated in FIG. 2.

In one or more embodiments, the semiconductor layers 103, 203, 303 have a combined thickness h₁ in a range of from about 1 μm to about 10 μm, including all values and subranges therebetween, including a range of from about 1 μm to about 9 μm, 1 μm to about 8 μm, 1 μm to about 7 μm, 1 μm to about 6 μm, 1 μm to about 5 μm, 1 μm to about 4 μm, 1 μm to about 3 μm, 3 μm to about 10 μm, 3 μm to about 9 μm, 3 μm to about 8 μm, 3 μm to about 7 μm, 3 μm to about 6 μm, 3 μm to about 5 μm, 3 μm to about 4 μm, 4 μm to about 10 μm, 4 μm to about 9 μm, 4 μm to about 8 μm, 4 μm to about 7 μm, 4 μm to about 6 μm, 4 μm to about 5 μm, 5 μm to about 10 μm, 5 μm to about 9 μm, 5 μm to about 8 μm, 5 μm to about 7 μm, 5 μm to about 6 μm, 6 μm to about 10 μm, 6 μm to about 9 μm, 6 μm to about 8 μm, 6 μm to about 7 μm, 7 μm to about 10 μm, 7 μm to about 9 μm, or 7 μm to about 8 μm.

The p-type layers 104, 204, 304 may comprise any appropriate materials known to one of skill in the art. In one or more embodiments, the p-type layers 10, 204, 304 comprise gallium nitride (GaN). The active region 116, 216, 316 may comprise any appropriate materials known to one of skill in the art. In one or more embodiments, the active region 116, 216, 316 is comprised of a Ill-nitride material multiple quantum wells (MQW), and a Ill-nitride electron blocking layer. The n-type layer 106, 206, 306 may comprise any appropriate materials known to one of skill in the art. In one or more embodiments, the n-type layer 106, 206, 306 may comprise any Group III-V semiconductors, including binary, ternary, and quaternary alloys of gallium (Ga), aluminum (Al), indium (In), and nitrogen (N), also referred to as III-nitride materials. Thus, in some embodiments, the n-type layer 106 comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the n-type layer 106, 206, 306 comprises gallium nitride (GaN). In one or more embodiments, the n-type layer 106, 206, 306 is doped with n-type dopants, such as silicon (Si) or germanium (Ge). In one or more embodiments, the n-type layer 106, 206, 306 includes one or more portions that are doped or that may include different levels of doping. According to one or more embodiments, the n-type layer 106 includes a highly doped n-type layer region (not shown), wherein “highly doped” refers to a doping level that is higher relative to other regions of the n-type layer 106. In one or more embodiments, one or more portions of the n-type layer 106 may be doped with one or more of silicon (Si), oxygen (O), boron (B), phosphorus (P), germanium (Ge), or manganese (Mn). It is noted that while FIGS. 3A-3K show an n-type layer 106 that does not specifically illustrate different regions of doping, it is to be understood that the n-type layer 106 of FIGS. 3A-3M can include one or more portions that are doped or that may include different levels of doping. According to various embodiments, the n-type layer 106 may have a dopant concentration significant enough to carry an electric current laterally through the layer.

According to one or more embodiments, as illustrated in FIGS. 3F-3K, 5A-5F, and 7E-71, the mesas can further include a P-contact layer 112, 212, 312 and a hard mask layer 114, 214, 314 disposed on the p-type layer 104, 204, 304. As shown, the P-contact layer 112, 212, 312 is deposited on the p-type layer 104, 204, 304 and the hard mask layer 114, 214, 314 is on the P-contact layer 112, 212, 312.

In one or more embodiments, the P-contact layer 112, 212, 312 may comprise any suitable p-metal known to the skilled artisan. In one or more embodiments, the P-contact layer 112, 212, 312 may comprise any suitable metal known to one of skill in the art. In one or more embodiments, the P-contact layer 112, 212, 312 comprises silver (Ag).

In one or more embodiments, the P-contact layer 112, 212, 312 may comprise a transparent conductive oxide material, such as, but not limited to indium tin oxide (ITO). In other embodiments, the P-contact layer 112, 212, 312 may be a composite mirror reflector layer. The composite mirror reflector layer may be made of multilayers of thin film materials of different refractive index.

In some embodiments, the P-contact layer 112, 212, 312 is deposited directly on the p-type layer 104, 204, 304. In other embodiments not illustrated, there may be one or more additional layer between the p-type layer 104, 204, 304 and the P-contact layer 112, 212, 312. In some embodiments, the hard mask layer 114, 214, 314 is deposited directly on the P-contact layer 112, 212, 312. In other embodiments not illustrated, there may be one or more additional layers between the hard mask layer 114, 214, 314 and the P-contact layer 112, 212, 312. The hard mask layer 114, 214, 314 and the P-contact layer 112, 212, 312 may be deposited by any appropriate technique known to the skilled artisan. In one or more embodiments, the hard mask layer 114, 214, 314 and P-contact layer 112, 212, 312 are deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the hard mask layer 114, 214, 314 may be fabricated using materials and patterning techniques which are known in the art. In some embodiments, the hard mask layer 114, 214, 314 comprises a metallic or dielectric material. Suitable dielectric materials include, but are not limited to, silicon oxide (SiO), silicon nitride (SiN), silicon carbide (SiC), aluminum oxide (AlOₓ), aluminum nitride (AlN) and combinations thereof. The skilled artisan will recognize that the use of formulas like SiO, to represent silicon oxide, does not imply any particular stoichiometric relationship between the elements. The formula merely identifies the primary elements of the film.

As illustrated in FIGS. 3F-3K, 5A-5F, and 7E-71, the device 100, 200, 300 further includes trenches 118a/118b, 218a/218b, 318a/318b disposed between the plurality of mesas 110, 210, 310. The trenches 118a/118b, 218a/218b, 318a/318b extend through the entire height h₁ of the semiconductor layers 103, 203, 303, the P-contact layer 112, 212, 312 and the hard mask 114, 214, 314. Prior to deposition of any materials or material layers within the trenches 118a/118b, 218a/218b, 318a/318b, the trenches 118a/118b, 218a/218b, 318a/318b include a bottom surface 123, 223, 323 comprising a top surface of the substrate 102, 202, 302 and side surfaces comprising sidewalls of the mesas 110, 210, 310 (e.g., a top sidewall portion formed by spacer layers 124, 224, 324, and a bottom sidewall portion 126, 226, 326 comprising a portion of the n-type layers 106, 206, 306 as illustrated in FIGS. 3F, 5A, and 7E). According to one or more embodiments, an electrically conductive material 132, 232, 332 is disposed within the trenches 118a/118b, 218a/218b, 318a/318b and can be deposited to fill the trenches after they are lined with one or more materials or material layers.

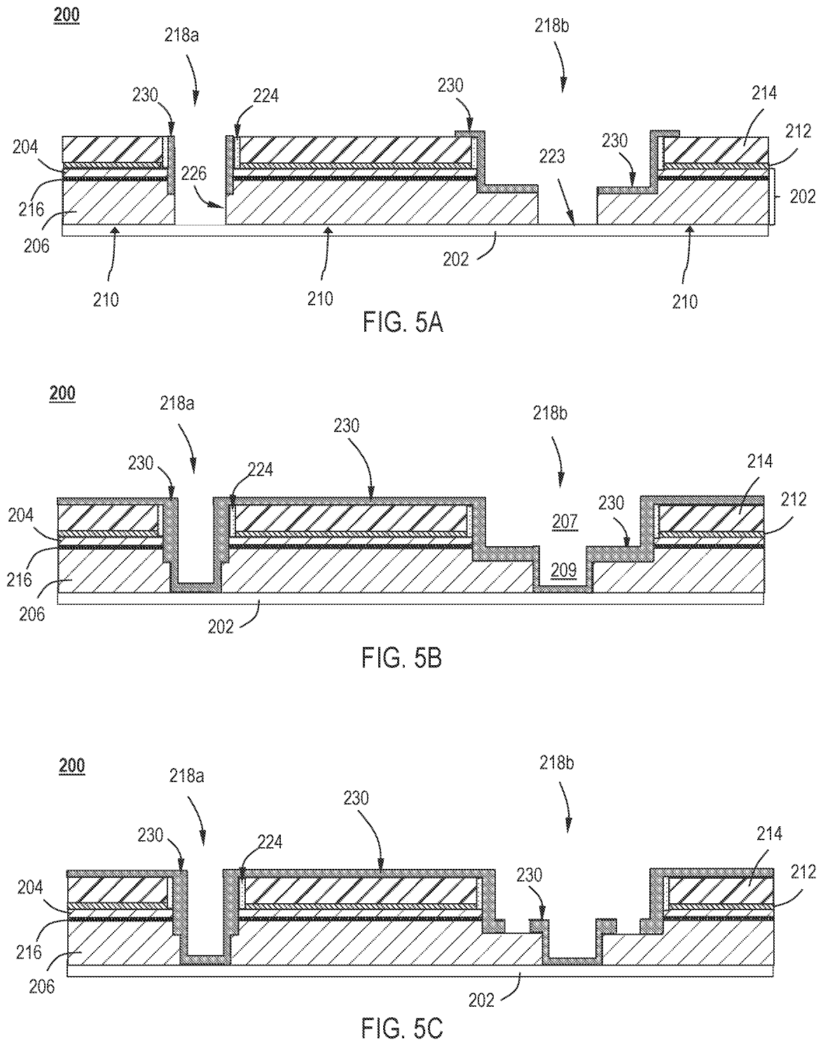

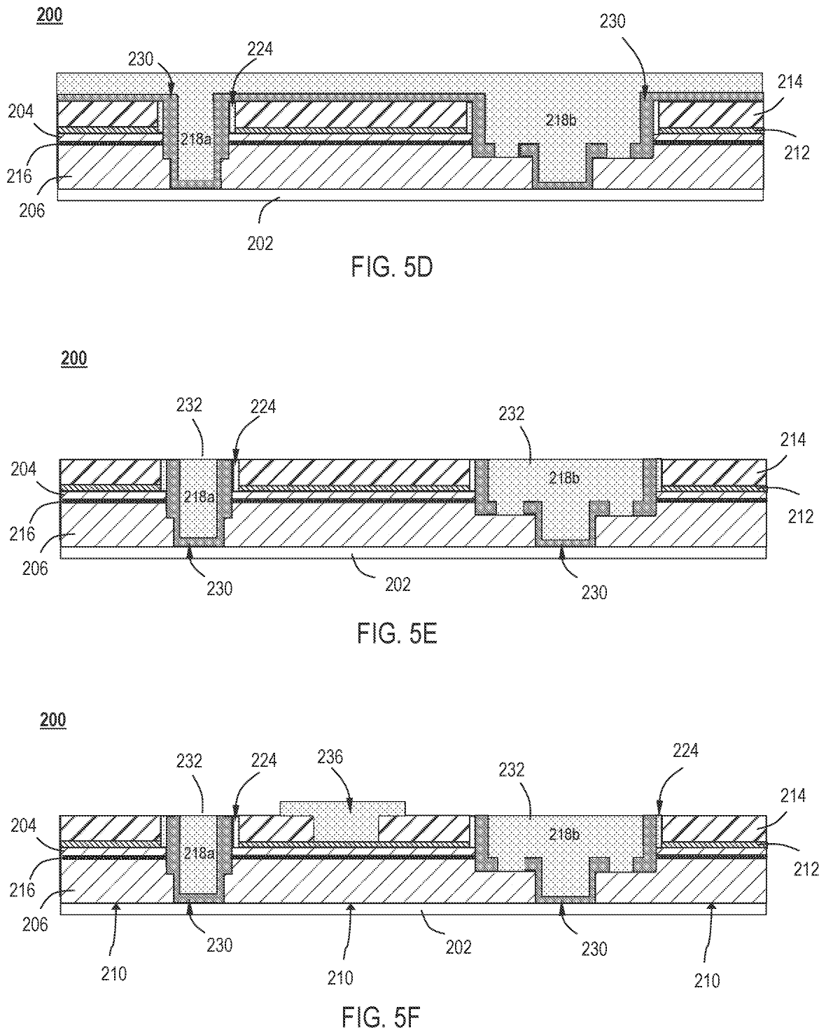

According to one or more embodiments, the trenches 118a/118b, 218a/218b, 318a/318b are at least partially lined with a dielectric layer 130, 230, 330. The dielectric layer 130, 230, 330 is disposed such that dielectric layer 130, 230, 330 is disposed (a) between the electrically conductive material 132 and the semiconductor layers 103, and in some embodiments (e.g., FIGS. 5F and 71) (b) between the electrically conductive material 132 and the substrate 102. The dielectric layer 130, 230, 330 can be disposed directly on the surfaces of trenches 118a/118b, 218a/218b, 318a/318b, or one or more intermediate layers or materials (not shown) can be disposed between the dielectric layer 130, 230, 330 and the surfaces of trenches 118a/118b, 218a/218b, 318a/318b. As described further herein, according to one or more embodiments, dielectric layer 130, 230, 330 is substantially conformal.

According to one or more embodiments, a spacer layer 124, 224, 324 is disposed between the electrically conductive material 132, 232, 332 within the trenches 118a/118b, 218a/218b, 318a/318b and an upper portion of the semiconductor layers 103, 203, 303. For example, the spacer layer 124, 224, 324 can be disposed between the electrically conductive material 132, 232, 332 within the trenches 118a/118b, 218a/218b, 318a/318b and the hard mask layer 114, 214, 314 and P-contact layer 112, 212, 312 for example as illustrated in FIGS. 3K, 5F, 7I. The spacer layer 124, 224, 324 can further extend downward so that it is also disposed between the electrically conductive material 132 within the trenches 118a/118b, 218a/218b, 318a/318b and one or more of the p-type layer 104, 204, 304, active region 116, 216, 316, and an upper portion of the n-type layers 106, for example as illustrated in FIG. 3K.

According to one or more embodiments, a p-type contact material 136, 236, 336 is disposed in a surface of a mesa 110, 210, 310. According to one or more embodiments, for example as illustrated in FIG. 3M, 5F, 71 a p-type contact material 136, 236, 336 is formed in the surface of the mesa 110, 210, 310 between trenches 118a/118b, 218a/218b, 318a/318b.

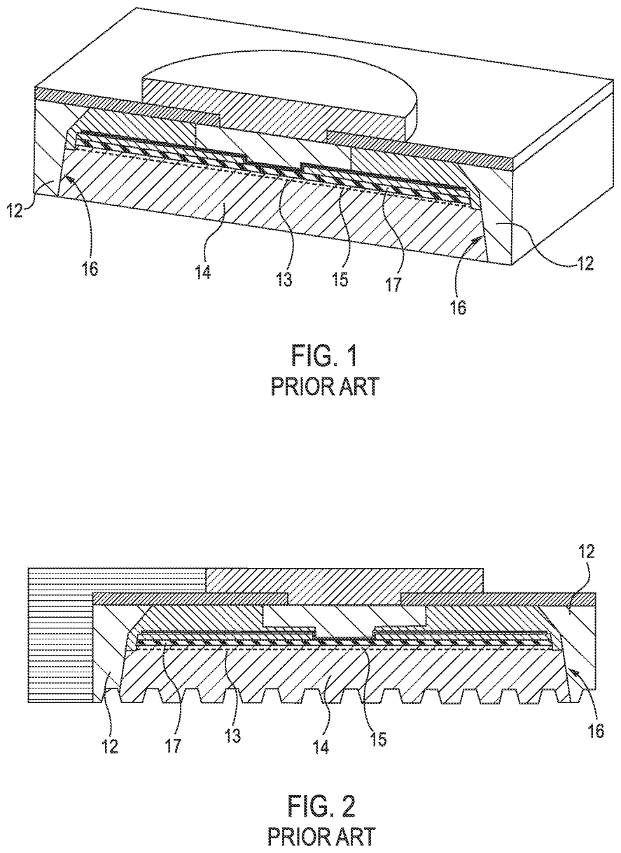

Typically, in order to electrically isolate p-type and n-type layers from metal (i.e., electrically conductive material 132, 232, 332 within trenches 118a/118b, 218a/218b, 318a/318b between pixels), a dielectric layer (junction spacer) is used at the portion of the trench sidewalls covering the active region 116, 216, 316 edges, and extending to a depth sufficient to etch away the active region 116, 216, 316 so as to access some highly doped layers (e.g., doped N-layer) of the semiconductor layers 103, 203, 303. This depth corresponds to a small fraction of the semiconductor layers 103, 203, 303 thickness (e.g. around ⅙), as illustrated in FIGS. 1-2. Embodiments of the present disclosure provide a dielectric layer 130, 230, 330 disposed such that n-contact formation is provided at the mesa 110, 210, 310 bottom over a limited region around the periphery of a pixel.

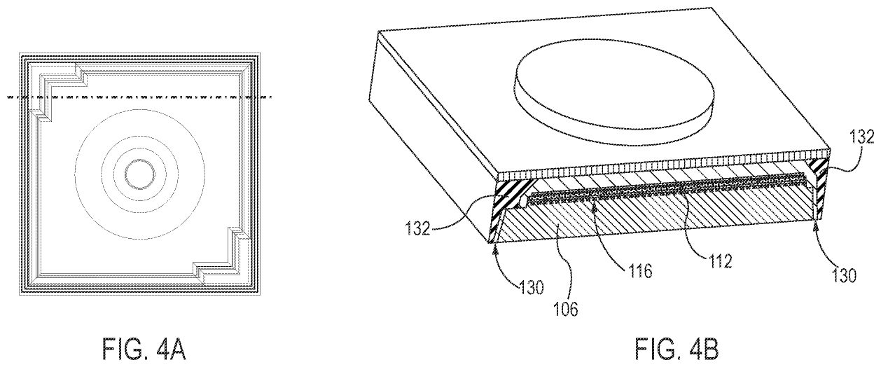

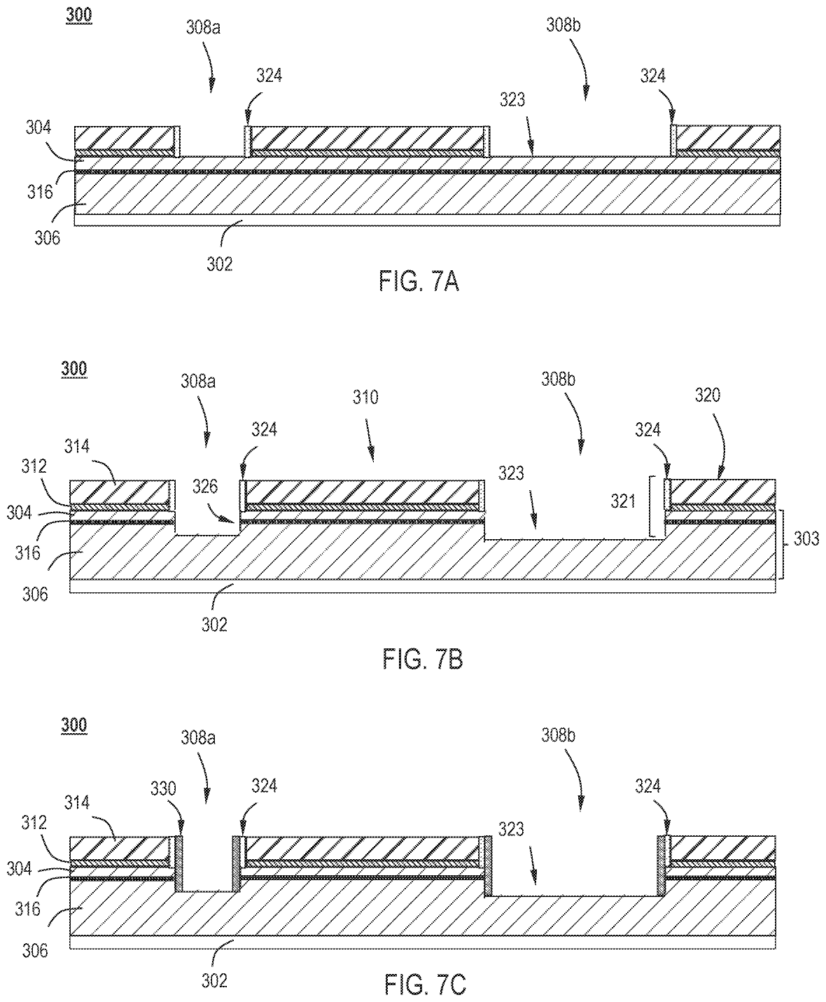

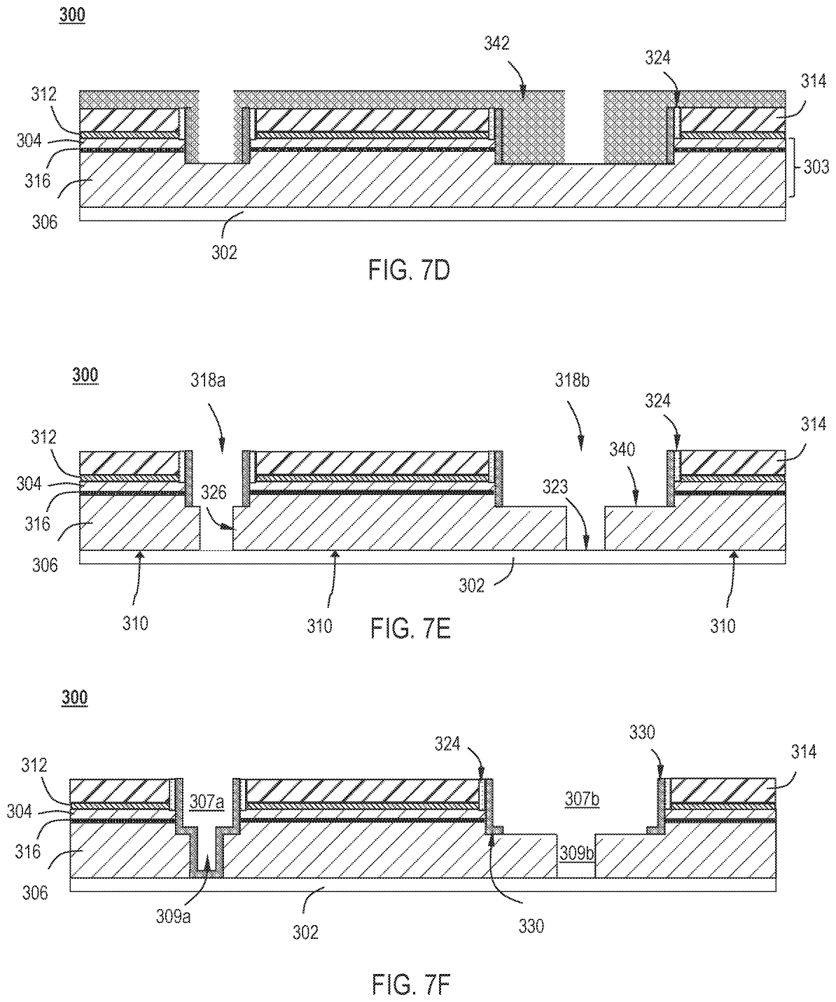

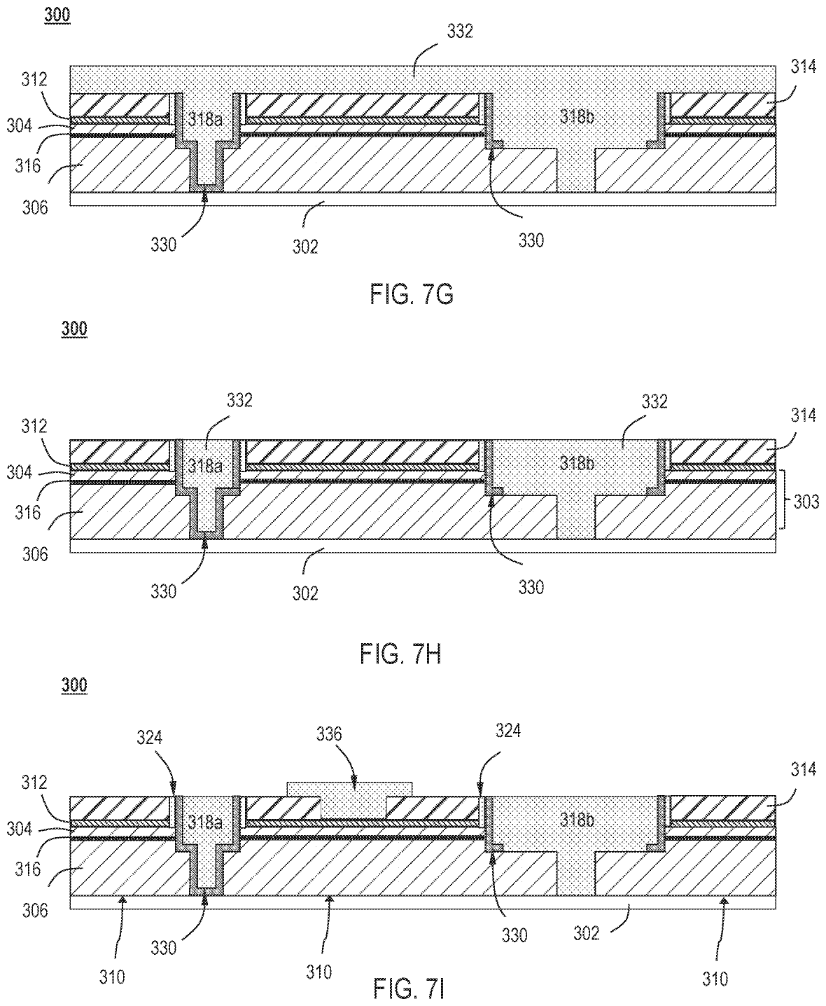

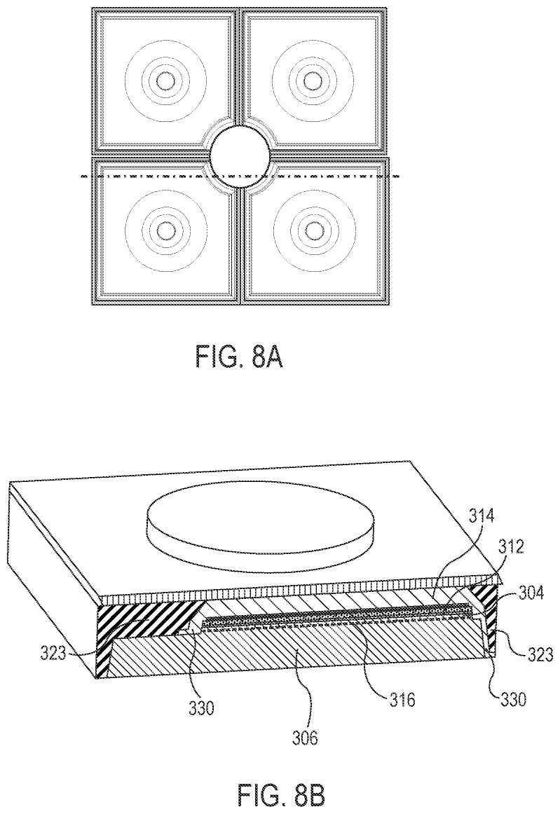

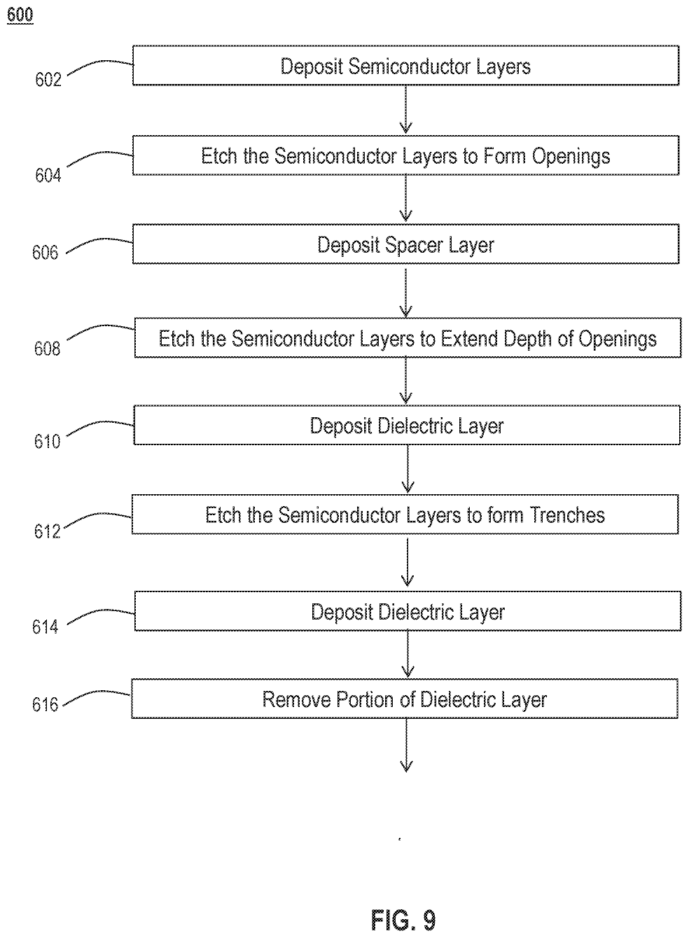

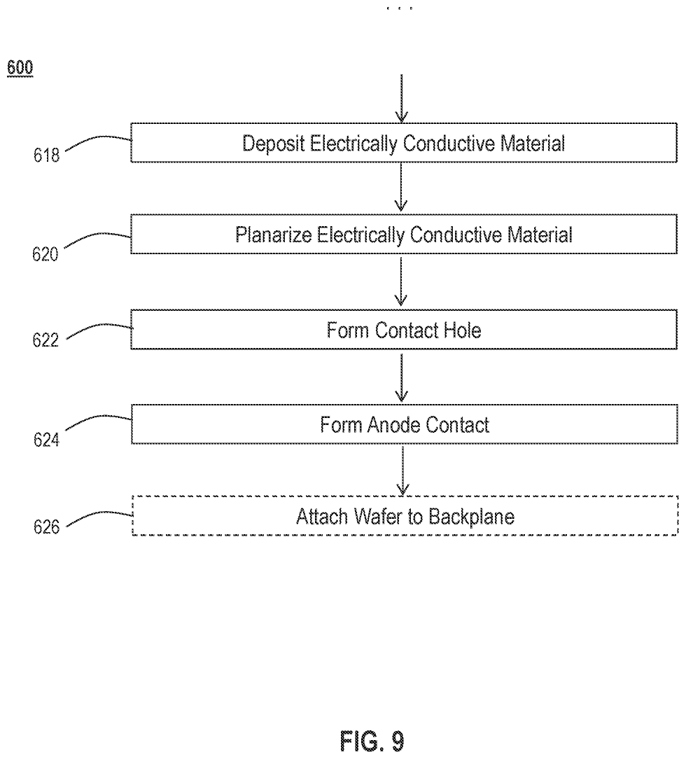

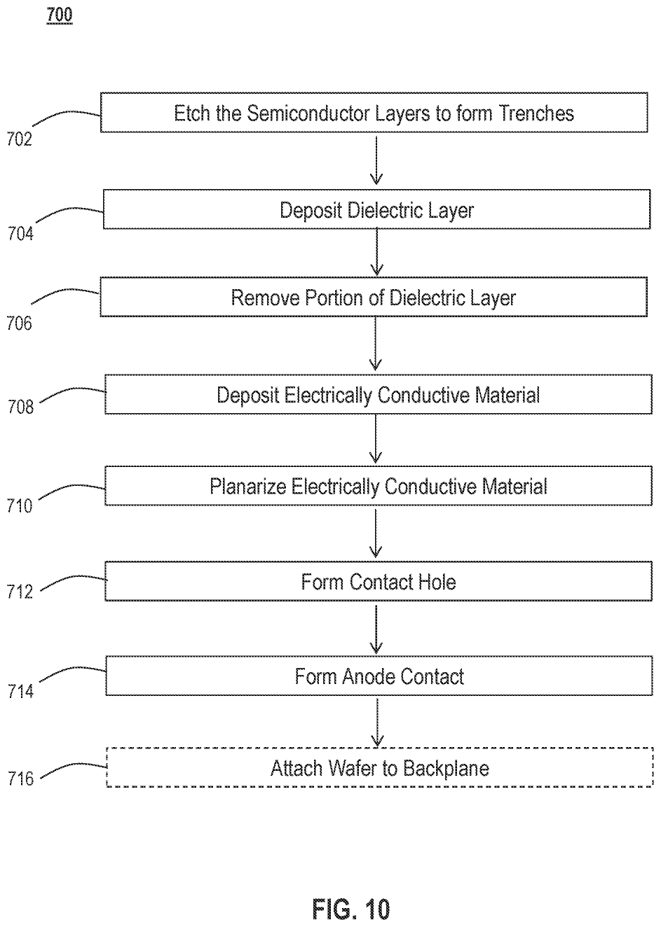

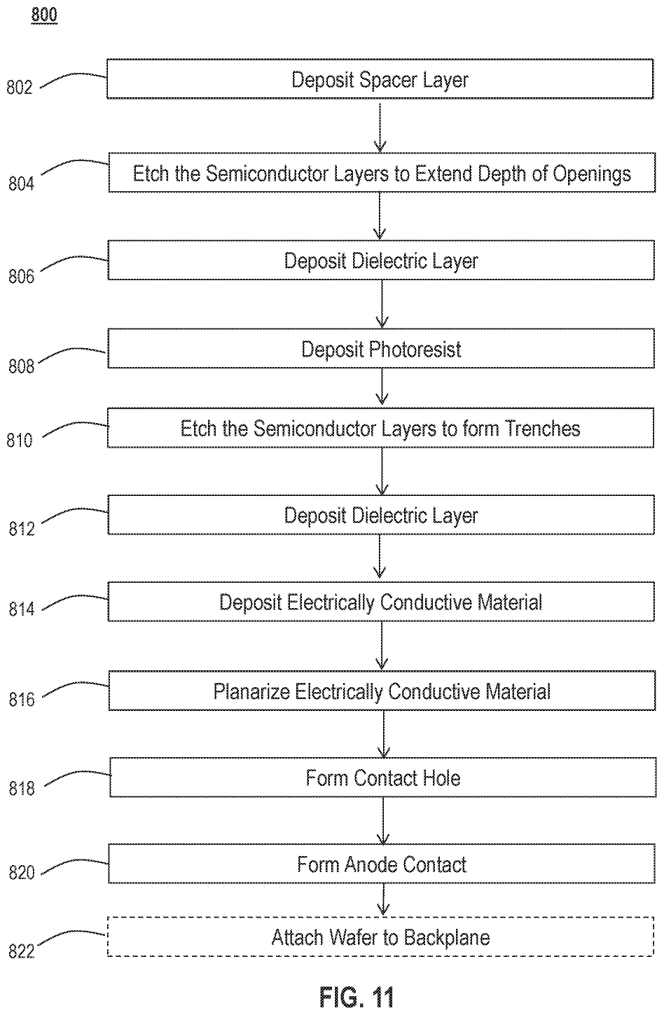

One or more embodiments of the disclosure are described with reference to the Figures. FIGS. 3A-3K and 4B illustrate cross-sectional views of a device 100 according to one or more embodiments which provides self-aligned N-contact without bottom dielectric coverage. FIGS. 5A-5F and 8C illustrate cross-sectional views of a device 200 according to one or more embodiments which provides regular N-contact alignment with bottom dielectric coverage. FIGS. 7A-7G and 8B illustrate cross-sectional views of a device 300 according to one or more embodiments which provides regular N-contact alignment with bottom dielectric coverage. An aspect of the disclosure pertains to a method of manufacturing a LED array. FIG. 9 illustrates a process flow diagram of a method 600 of manufacturing an LED device according to one or more embodiments providing self-aligned N-contact without bottom dielectric coverage. FIG. 10 illustrates a process flow diagram of a method 700 of manufacturing an LED device according to one or more embodiments providing regular N-contact alignment with bottom dielectric coverage. FIG. 11 illustrates a process flow diagram of a method 800 of manufacturing an LED device according to one or more embodiments providing regular N-contact alignment with bottom dielectric coverage. Reference to regular N-contact alignment as used herein refers to when a mask is needed when etching the dielectrics for the n-contact, as opposed to the maskless self-aligned n-contacts of one or more embodiments.

With reference to FIG. 3A and FIG. 9, in one or more embodiments, the first part of the epitaxy (operation 602) involves the growth of an n-type layer 106 and may be the same as in a conventional LED growth run using a sapphire or other applicable growth substrate 102. The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate 102 is not patterned and can be considered to be flat or substantially flat. In other embodiments, the substrate 102 is a patterned substrate.

In one or more embodiments, the n-type layer 106 is deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a Ill-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein, according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein, according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similarly, to a thermal ALD process, a purge step may be conducted between the deliveries of each of the reactants.

As used herein, according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, a LED device 100 is manufactured by placing the substrate 102 in a metalorganic vapor-phase epitaxy (MOVPE) reactor so that the LED device layers are grown epitaxially.

In one or more embodiments, after the growth of the n-type layers 106, an active region 116, and p-type layers 104 are grown using deposition techniques known to one of skill in the art.

In one or more embodiments, after the growth of the active region 116 and p-type layers 104, a P-contact layer 112, and hard mask 114 are deposited using deposition techniques known to one of skill in the art.

Referring to FIG. 3B and FIG. 9, at operation 604, a plurality of openings 108a, 108b are formed. In one or more embodiments, the openings 108a, 108b may be formed using a conventional directional etching process, such as dry etching. According to one or more embodiments, the hard mask layer 114 and P-contact layer 112 are patterned to form the plurality of openings 108a, 108b in the hard mask layer 114 and P-contact layer 112, exposing a top surface of the semiconductor layers 103. According to the embodiment depicted in FIG. 3B-3K, the openings 108a, 108b may be extended in multiple operations to form mesas 110 separated by trenches 118a, 118b. For example, as depicted in FIG. 3B, a first etching operation (operation 804) may form openings 108a, 108b that extend from the top surface 120 of the hard mask layer 114 to the n-type layers 106. According to one or more embodiments, for example as illustrated in FIG. 3B, the depth of the openings 108a, 108b extend to a top surface of the p-type layers 104. The openings 108a, 108b formed at operation 604 and illustrated in FIG. 3B may comprise at least one sidewall 121 and a bottom surface 123. In one or more embodiments, sidewalls 121 (formed at operation 604) of a first opening 108a may have a height that is about the same as the height of the sidewalls 121 of a second opening 108b (where “height” can be measured by the depth of the openings from the top surface of the hard mask layer 114). In other embodiments, the first opening 108a may have a height that is different than the height of the second opening 108b. In one or more embodiments, the sidewalls 121 may be completely vertical as illustrated in FIG. 3B or may have an angle of inclination up to 45 degrees. On one or more embodiments, for example as illustrated in FIG. 3B, the width of the openings 108a, 108b (i.e., distance between sidewalls 121 within the openings 108a, 108b) may be different such that the width of the opening 108a is less than the width of the opening 108b.

In one or more embodiments, the hard mask layer 114 and P-contact layer 112 is patterned according to any appropriate patterning technique known to one of skill in the art. In one or more embodiments, the hard mask layer 114 and P-contact layer 112 are patterned by etching. According to one or more embodiments, conventional masking, wet etching and/or dry etching processes can be used to pattern the hard mask layer 114 and the P-contact layer 112.

In other embodiments, a pattern is transferred to the hard mask layer 114 and P-contact layer 112 using nanoimprint lithography. In one or more embodiments, the substrate 102 is etched in a reactive ion etching (RIE) tool using conditions that etch the hard mask layer 114 and P-contact layer 112 efficiently but etch the p-type layer 104 very slowly or not at all. In other words, the etching is selective to the hard mask layer 114 and P-contact layer 112 over the p-type layer 104. In a patterning step, it is understood that masking techniques may be used to achieve a desired pattern.

Referring to FIG. 3C and FIG. 9, at operation 606, a spacer layer 124 is deposited on the sidewalls 121 of the plurality of opening 108a, 108b. According to one or more embodiments, the spacer layer 124 can further be deposited on the top surface of the hard mask layer 114 and bottom surface 123 of the plurality of opening 108a, 108b. According to one or more embodiments, the spacer layer 124 is deposited along the entire length of the sidewalls 121, bottom surface 123, and the entire length of the top surface of the hard mask layer 114. According to one or more embodiments, the spacer layer 124 is substantially the same thickness along the entire length of the sidewalls 121. As used herein, “substantially the same thickness” refers to a layer where the thickness is about the same throughout and varies in thickness by less than or equal to about 5%, 2%, 1% or 0.5%. The spacer layer 124 may be formed using a conventional deposition technique, such as, for example, CVD, PECVD, ALD, evaporation, sputtering, chemical solution deposition, spin-on deposition, or other like processes. Deposition of the material that forms the spacer layer 124 is typically done conformally, followed by etching to provide the spacer layer 124 only on the sidewalls 121, but not on the top surface of the hard mask layer 114 or on the bottom surface 123, thus providing the structure illustrated in FIG. 3C.

The spacer layer 124 may comprise any suitable dielectric material known to the skilled artisan. As used herein, the term “dielectric” refers to an electrical insulator material that can be polarized by an applied electric field. In one or more embodiments, the spacer layer 124 comprises a dielectric that includes, but is not limited to, oxides, e.g., silicon oxide (SiO₂), aluminum oxide (Al₂O₃), nitrides, e.g., silicon nitride (Si₃N₄). In one or more embodiments, the spacer layer 124 comprises silicon nitride (Si₃N₄). In other embodiments, the spacer layer 124 comprises silicon oxide (SiO₂). In some embodiments, the spacer layer 124 composition is non-stoichiometric relative to the ideal molecular formula. For example, in some embodiments, the spacer layer 124 includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO). In one or more embodiments, the spacer layer 124 has a thickness greater than about 10 nm, or greater than about 20 nm, or greater than about 100 nm. In other embodiments, the spacer layer 124 has a thickness in a range of from 10 nm to 500 nm.

In some embodiments, the spacer layer 124 may be a distributed Bragg reflector (DBR). As used herein, a “distributed Bragg reflector” refers to a structure (e.g., a mirror) formed from a multilayer stack of alternating thin film materials with varying refractive index, for example high-index and low-index films.

Referring to FIG. 3D and FIG. 9, at operation 608, the plurality of openings 108a, 108b are further etched so that the openings 108a, 108b extend a further depth through the p-type layers 104, the active region 116, and into the n-type layers 106. In one or more embodiments, the extension of openings 108a, 108b at operation 608 may be carried out using a conventional directional etching process, such as dry etching. As illustrated in FIG. 3D, the openings 108a, 108b now include at least one sidewall comprising a top sidewall portion formed by the spacer layer 124 and a bottom sidewall portion 126 comprising the p-type layers 104, the active region 116, and a portion of the n-type layers 106 exposed by operation 608. As further illustrated in FIG. 3D, the openings 108a, 108b now include a bottom surface 123 comprising a portion of the n-type layers 106 exposed by operation 608. In one or more embodiments, a first opening 108a formed at operation 608 may have total a height (comprising the spacer layer 124 and the bottom sidewall portion 126) that is about the same as the height of a second opening 108b. In other embodiments, the first opening 108a may have a height that is different than the height of the second opening 108b. In one or more embodiments, the sidewalls of openings 108a, 108b formed at operation 608 may be completely vertical as illustrated in FIG. 3D or may have an angle of inclination up to 45 degrees.

Referring to FIG. 3E and FIG. 9, at operation 610, a dielectric layer 130 is deposited along the entire length of the sidewalls of openings 108a, 108b formed at operation 808. According to one or more embodiments, for example as illustrated in FIG. 3E, the dielectric layer 130 is deposited so that it lines the sidewalls of openings 108a and 108b (i.e., lines the sidewalls 121 formed at operation 608 illustrated in FIG. 3D, which includes the surface of the spacer layer 124 and the bottom sidewall portion 126), lines at least a portion of the top surface 120 of the hard mask layer 114 adjacent opening 108b, and lines at least a portion of the bottom surface 123 of opening 108a. According to one or more embodiments, the dielectric layer 130 is deposited so that it lines a portion of the bottom surface 123 of opening 108b, leaving a portion of the bottom surface 123 exposed. For example, a central portion of the bottom surface 123 of opening 108a may remain exposed, as illustrated in FIG. 3E. In one or more embodiments, the dielectric layer 130 is deposited to line the entire hard mask layer 114, the bottom surface of opening 108a, and the entire bottom surface 123 of opening 108b followed by partial removal of the dielectric layer 130 (e.g., by etching) to provide the structure in FIG. 3E. The dielectric layer 130 formed at operation 610 may be formed using a conventional deposition technique, such as, for example, CVD, PECVD, ALD, evaporation, sputtering, chemical solution deposition, spin-on deposition, or other like processes.

In one or more embodiments, the dielectric layer 130 may comprise any suitable dielectric material known to the skilled artisan. As used herein, the term “dielectric” refers to an electrical insulator material that can be polarized by an applied electric field. In one or more embodiments, the dielectric layer 130 may comprise any suitable dielectric material known to the skilled artisan. In some embodiments, the dielectric layer 130 comprises a low-refractive index material. In some embodiments, the dielectric material comprises one of more of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ). While the term “silicon oxide” may be used to describe the dielectric layer 130, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. In one or more embodiments, the dielectric layer 130 comprises silicon oxide. In one or more embodiments, the dielectric layer 130 comprises the same material as the spacer layer 124 formed at operation 606.

Referring to FIG. 3F and FIG. 9, at operation 612, the plurality of openings 108a, 108b are further etched to form mesas 110 separated by trenches 118a, 118b extending through the entire depth of the n-type layers 106 to a surface of the substrate 102. In one or more embodiments, extension of openings 108a, 108b at operation 612 may be carried out using a conventional directional etching process, such as dry etching. As illustrated in FIG. 3F, the trenches 118a, 118b include at least one sidewall comprising a top sidewall portion formed by the dielectric layer 130 and a bottom sidewall portion 126 comprising a portion of the n-type layers 106. The trenches 118a, 118b further include a bottom surface 123 comprising a top surface of the substrate 102. In one or more embodiments, the sidewalls of trench 118a formed at operation 612 may be completely vertical as illustrated in FIG. 3F or may have an angle of inclination up to 45 degrees. In one or more embodiments, the trench 118b includes an upper wider portion 107 disposed between the hard mask layer, P-contact layer 112, n-type layers 104, active region 116, and an upper portion of the p-type layers 106, and a bottom narrower portion 109 disposed between a lower portion of the n-type layers 106. According to one or more embodiments, during operation 612, the dielectric layer 130 in openings 108a, 108b serve as etch stops so that etching carried out at operation 612 removes the portions of the n-type layers 106 in the openings 108a, 108b vertically downward between the dielectric layer 130.

Referring to FIG. 3G and FIG. 9, at operation 614, show formation of a dielectric layer 130 within the trenches 118a, 118b and on the top surface 120 of the hard mask layer 114. As illustrated, the dielectric layer 130 lines the entire sidewalls of the trenches 118a, 118b and the bottom surface 123 (i.e., exposed top surface of the substrate 102) of the trenches 118a, 118b. According to one or more embodiments, for example as illustrated in FIG. 3G, the dielectric layer 130 has a thicker portion on the top surface of the hard mask layer 114 adjacent the trench 118b which is formed by deposition of dielectric layer 130 from operation 614 over the dielectric layer formed in operation 610. The dielectric layer 130 may be formed using a conventional deposition technique, such as, for example, CVD, PECVD, ALD, evaporation, sputtering, chemical solution deposition, spin-on deposition, or other like processes.

In one or more embodiments, each layer of dielectric formed in each individual operation (i.e., operation 610 illustrated in FIG. 3E and operation 614 illustrated in FIG. 3G) is substantially conformal. As used herein, a layer which is “substantially conformal” refers to a layer where the thickness is about the same throughout. A layer which is substantially conformal varies in thickness by less than or equal to about 5%, 2%, 1% or 0.5%. In one or more embodiments, after operation 614, a dielectric layer 130 forms on the entirety of the at least one sidewall and on the bottom surfaces 123 of the trenches 118a, 118b and on the top surface 120 of the hard mask layer 114.

In one or more embodiments, each of the deposited dielectric layers 130 formed at operations 610 and 614 have a minimum thickness greater than about 10 nm, or greater than about 20 nm, or greater than about 100 nm, or greater than about 300 nm, or greater than about 500 nm, or greater than about 1000 nm. In other embodiments, each of the deposited dielectric layers 130 has a thickness in a range of from about 10 nm to about 500 nm. The dielectric layer 130 thereby provides a total internal reflection (TIR) means to increase side-wall reflectivity.

Referring to FIG. 3H and FIG. 9, at operation 616, portions of the dielectric layer 130 are removed. According to one or more embodiments, one or more portions of the dielectric layer 130 lining the surface of the substrate 102 (i.e., bottom surface 123 of the trenches 118a, 118b), one or more portions of the dielectric layer 130 lining horizontal surfaces 140 of the n-type layers 106 within trench 118b, and one or more portions of the dielectric layer 130 lining the hard mask layer 114 are removed. According to one or more embodiments, for example as illustrated in FIG. 3H, after removal of portions of the dielectric layer 130 at operation 616, the dielectric layer 130 may remain disposed only on the trench 118a, 118b sidewalls (i.e., vertical sidewalls within trenches 118a, 118b).

The portions of the dielectric layer 130 may be removed using a conventional directional etching process, such as dry etching. In one or more embodiments, for example as illustrated in FIG. 3H, when portions of the dielectric layer 130 are removed in operation 616, horizontal portions 140 of the n-type layers 106 in the trench 118b are exposed, the bottom surfaces 123 of the trenches 118a, 118b are exposed, and the hard mask layer 114 is exposed.

Referring to FIG. 3I and FIG. 9, at operation 618, an electrically conductive material 132 is deposited. According to one or more embodiments, the electrically conductive material 132 is deposited to fill the trenches 118a, 118b and cover the exposed upper surfaces of the device 100 (e.g., exposed hard mask layer 114, horizontal portions 140 of the n-type layers 106 in the trench 118b, exposed substrate surface, and exposed dielectric layer 130). The electrically conductive material 132 can suitably be selected from any conventional electrically conductive materials such as, for example, electroplated copper (Cu).

Referring to FIG. 3J and FIG. 9, at operation 620, processing is carried out to remove excess electrically conductive material 132. In one or more embodiments, the processing includes planarizing, etching, and/or polishing. As used herein, the term “planarizing” refers to a process of smoothing surfaces and includes, but is not limited to, chemical mechanical polishing/planarization (CMP), etching, and the like. According to one or more embodiments, the deposited electrically conductive material 132 is planarized to remove electrically conductive material 132 disposed outside of the trenches 118a, 118b (i.e. not disposed within the sidewalls of the trenches). As illustrated in the embodiment shown by FIG. 3J, the resulting upper surface of the device 100 includes the hard mask layer 114 surrounding the trenches 118a, 118b, upper surfaces of spacer layers 124, upper surfaces of the dielectric layer 130 lining the trenches 118a, 118b, and the planarized electrically conductive material 132 disposed within the trenches 118a, 118b.

Referring to FIG. 3K and FIG. 9, at operations 622 and 624, a contact opening is formed in the hard mask layer 114 and a p-type contact material 136 (or an anode contact metal) is deposited in the contact opening 134. According to one or more embodiments, for example as illustrated in FIG. 3K, the contact opening is formed in the hard mask layer 114 between trenches 118a and 118b. The contact opening can be formed by etching. In one or more embodiments, the contact opening may be formed using a conventional directional etching process, such as dry etching. According to one or more embodiments, the p-type contact material 136 may comprise any suitable material known to the skilled artisan. In one or more embodiments, the p-type contact material 136 comprises a p-contact material selected from one or more of aluminum (Al), silver (Ag), gold (Au), platinum (Pt), and palladium (Pd). In specific embodiments, the p-type contact material 136 comprises silver (Ag). In some embodiments, additional metals may be added in small quantities to the p-type contact material 136 as adhesion promoters. Such adhesion promoters, include, but are not limited to, one or more of nickel (Ni), titanium (Ti), and chromium (Cr).

In later stages of processing, the entire device 100 or a piece of the device 100 is bonded to a system substrate such as a display backplane to form a system (e.g., FIG. 9, at operation 626). An array of landing pads may be arranged on the system substrate with dimensions aligned to those of the bonding pads on the device 100. The landing pads may be connecting to display driver circuitry in the system substrate. In one or more embodiments, after bonding, the substrate 102 is removed using a process such as laser lift-off if the substrate is a UV-transparent material such as sapphire.

According to one or more embodiments, a LED pixel die is provided with self-aligned n-contact formation at the pixel corners, for example as illustrated in FIG. 4A. Using the LED pixel die formed according to the present methods as described above in connection with FIGS. 3A-3K and 10, LED arrays can be provided having a variety of contact geometries. One embodiment of an LED array according to the present invention is illustrated in FIGS. 3K and 4A-4C. As illustrated, an LED device 100 is provided in which an electrically conductive material 132 disposed in the trench (e.g., 118a, 118b) is separated from semiconductor layers (N-type layer 104, an active layer 116, and a P-type layer 106) forming sidewalls of a mesa 110. According to one or more embodiments, dielectric layer 130 extends between the semiconductor layers 104, 116, 106 and the electrically conductive material 132 along an increased length of the trench (118a, 118b). As such, the dielectric layer 130 optically isolates the trench 118a, 118b.

The present disclosure is in contrast with prior designs in which a metal contact 16 is formed between the trench 12 and the n-type layer 14 (as illustrated in FIGS. 1-2). The efficacy of such prior designs is severely limited by optical performance. In particular, one of the main reasons for loss of optical performance is the absorption of the trench material (i.e., metal). Without intending to be bound by theory, it was discovered that the n-contact (metal contact 16 shown in FIGS. 1 and 2) is the main contributor to loss in optical power, and an increase in efficiency can be achieved by at least partially optically isolating the trench from the semiconductor layers. According to embodiments of the disclosure, by at least partially optically isolating the trench from the semiconductor layers using the disclosed methods, materials, and structures, the ratio of lumen output (Im) to electrical power consumption (W) (i.e., Im/W) is improved. According to embodiments of the disclosure, Im/W improvements of at least about 5%, at least about 6%, at least about 7%, at least about 8%, at least about 9%, and at least about 10% are achieved by at least partially optically isolating the trench from the semiconductor layers using the disclosed methods, materials, and structures. According to embodiments of the disclosure, Im/W improvements of about 10% to about 15% are achieved by at least partially optically isolating the trench from the semiconductor layers using the disclosed methods, materials, and structures. According to embodiments of the disclosure, by at least partially optically isolating the trench from the semiconductor layers using the disclosed methods, materials, and structure, the efficiency of photo extraction from the LED is increased.

According to another embodiment, as illustrated in FIGS. 5A-5F and FIG. 10, a device 200 is provided having regular N-contact alignment with bottom dielectric coverage. FIG. 5A, operation 702 corresponds to the prior described embodiment at FIG. 3F, operation 612. As such, according to one or more embodiments, prior to FIG. 5A, operation 702, each of FIGS. 3A-3E, operations 602-610 are carried out as set forth above. It is noted that various elements in FIGS. 3A-3K are numbered as device 100, p-type layers 104, n-type layers 106, etc., while corresponding elements in FIGS. 5A-5F are numbered as device 200, p-type layers 204, n-type layers 206, etc. All of the materials, methods, dimensions, and other details described in connection with the embodiment of FIGS. 3A-3K and 11 apply to the embodiment of FIGS. 5A-5F and 11.

With reference to FIG. 5A and FIG. 10, at operation 702, a plurality of openings (previously formed, for example, in accordance with FIGS. 3A-3E, and FIG. 9 operations 602-610) are further etched to form mesas 210 separated by trenches 218a, 218b extending through the entire depth of the n-type layers 206 to a surface of the substrate 202. In one or more embodiments, etching at operation 702 may be carried out using a conventional directional etching process, such as dry etching. As illustrated in FIG. 5A, the trenches 218a, 218b include at least one sidewall comprising a top sidewall portion formed by the dielectric layer 230 and a bottom sidewall portion 226 comprising a portion of the n-type layers 206. The trenches 218a, 218b further include a bottom surface 223 comprising a top surface of the substrate 202. In one or more embodiments, the sidewalls of trench 218a formed at operation 702 may be completely vertical as illustrated in FIG. 5A or may have an angle of inclination up to 45 degrees. In one or more embodiments, the trench 218b includes an upper wider portion 207 disposed between the hard mask layer, P-contact layer 112, n-type layers 104, active region 116, and an upper portion of the p-type layers 106, and a bottom narrower portion 209 disposed between a lower portion of the n-type layers 206. According to one or more embodiments, during operation 702, the dielectric layer 230 lining sidewalls of the openings serve as etch stops so that etching carried out at operation 702 removes the portions of the n-type layers 206 in the openings vertically downward between the dielectric layer 230 (e.g., where the openings 108a, 108b and dielectric layer 130 prior to etching are illustrated in FIG. 3E).

Referring to FIG. 5B and FIG. 10, at operation 704, show formation of a dielectric layer 230 within the trenches 218a, 218b and on the hard mask layer 214. As illustrated, the dielectric layer 230 lines the entire sidewalls of the trenches 218a, 218b and the bottom surface 223 (i.e., exposed top surface of the substrate 202) of the trenches 218a, 218b. According to one or more embodiments, for example as illustrated in FIG. 5B, the dielectric layer 230 is substantially conformal on the hard mask layer 214. This is in contrast with the embodiment shown and described in FIG. 3G in which the dielectric layer 130 has a thicker portion on the hard mask layer 114 adjacent the trench 118b. The dielectric layer 230 may be formed using a conventional deposition technique, such as, for example, CVD, PECVD, ALD, evaporation, sputtering, chemical solution deposition, spin-on deposition, or other like processes.

In one or more embodiments, for example, as illustrated in FIG. 5B, the dielectric layer 230 extending along the hard mask layer 214, lining the trench 218b, lining the bottom surface 223 of trenches 218a, 218b, and lining the bottom sidewall portion 226 of trench 218a (as referenced in FIG. 5A) is substantially conformal. According to one or more embodiments, the upper sidewall portion of trench 218a includes an additional spacer layer (e.g., as formed in prior FIG. 3C, operation 606) and an additional dielectric layer (e.g., as formed in prior FIG. 3E, operation 610) and, thus, is not described as substantially conformal with the remainder of the dielectric layer. In one or more embodiments, after operation 704, a dielectric layer 230 forms on the entirety of the hard mask layer 214 and the entirety of the sidewalls, horizontal surfaces, and bottom surfaces 223 of the trenches 218a, 218b.

In one or more embodiments, the dielectric layer 230 in FIG. 5B (formed as a result of operations 610 and 614) has a minimum thickness greater than about 10 nm, or greater than about 20 nm, or greater than about 100 nm, or greater than about 300 nm, or greater than about 500 nm, or greater than about 1000 nm. In other embodiments, the dielectric layer 230 in FIG. 5B (formed as a result of operations 610 and 614) has a minimum thickness in a range of from about 10 nm to about 500 nm. The dielectric layer 230 thereby provides a total internal reflection (TIR) means to increase side-wall reflectivity.

Referring to FIG. 5C and FIG. 10, at operation 706, portions of the dielectric layer 230 are removed. In the embodiment illustrated, the trench 218b includes an upper wider portion 207 and a lower narrower portion 209. The upper wider portion 207 includes vertical sidewalls lined with a dielectric layer 230 and inwardly extending horizontal surface portions 240 of the n-type layers 206 partially lined with a dielectric layer 230 with a central portion of each horizontal portion 240 exposed. The lower narrower portion 209 of the trench 218b is illustrated as completely lined with a dielectric layer 230. According to one or more embodiments, as illustrated in FIG. 5C, a central portion of the dielectric layer 230 lining each of the horizontal surface portions 240 is removed.

The portions of the dielectric layer 230 may be removed using a conventional directional etching process, such as dry etching. In one or more embodiments, for example as illustrated in FIG. 5C, when portions of the dielectric layer 230 are removed in operation 706, only a central portion of the horizontal surface portions 240 of the n-type layers 106 in the trench 218b are exposed.

Referring to FIG. 5B and FIG. 10, at operation 708, an electrically conductive material 232 is deposited. According to one or more embodiments, the electrically conductive material 232 is deposited to fill the trenches 218a, 218b and cover the exposed upper surfaces of the device 200 (e.g., exposed dielectric layer 230 lining the hard mask layer 214). The electrically conductive material 232 can suitably be selected from any conventional electrically conductive materials such as, for example, electroplated copper (Cu).

Referring to FIG. 5E and FIG. 10, at operation 710, processing is carried out to remove excess electrically conductive material 232. In one or more embodiments, the processing includes planarizing, etching, and/or polishing. As used herein, the term “planarizing” refers to a process of smoothing surfaces and includes, but is not limited to, chemical mechanical polishing/planarization (CMP), etching, and the like. According to one or more embodiments, the deposited electrically conductive material 232 is planarized to remove electrically conductive material 232 disposed outside of the trenches 218a, 218b (i.e. not disposed within the sidewalls of the trenches), and portions of the dielectric layer 230 disposed on the top surface of the hard mask layer 214 are further removed as illustrated in FIG. 5E. As illustrated in the embodiment shown by FIG. 5E, the resulting upper surface of the device 200 includes the top surface of the hard mask layer 114 surrounding the trenches 218a, 218b, upper surfaces of spacer layers 224, upper surfaces of the dielectric layer 230 lining the trenches 218a, 218b, and the planarized electrically conductive material 232 disposed within the trenches 218a, 218b.

Referring to FIGS. 5F and 11, at operations 712 and 714, a contact opening is formed in the surface of the hard mask layer 214, and a p-type contact material 236 (or an anode contact metal) is deposited in the contact opening. According to one or more embodiments, for example as illustrated in FIG. 5F, the contact opening is formed in the surface of the hard mask layer 214 between trenches 218a and 218b. The contact opening can be formed by etching. In one or more embodiments, the contact opening may be formed using a conventional directional etching process, such as dry etching. According to one or more embodiments, the p-type contact material 236 may comprise any suitable material known to the skilled artisan. In one or more embodiments, the p-type contact material 236 comprises a p-contact material selected from one or more of aluminum (Al), silver (Ag), gold (Au), platinum (Pt), and palladium (Pd). In specific embodiments, the p-type contact material 236 comprises silver (Ag). In some embodiments, additional metals may be added in small quantities to the p-type contact material 236 as adhesion promoters. Such adhesion promoters, include, but are not limited to, one or more of nickel (Ni), titanium (Ti), and chromium (Cr).

In later stages of processing, the entire device 200 or a piece of the device 200 is bonded to a system substrate such as a display backplane to form a system (e.g., FIG. 10, at operation 716). An array of landing pads may be arranged on the system substrate with dimensions aligned to those of the bonding pads on the device 200. The landing pads may be connecting to display driver circuitry in the system substrate. In one or more embodiments, after bonding, the substrate 202 is removed using a process such as laser lift-off if the substrate is a UV-transparent material such as sapphire.

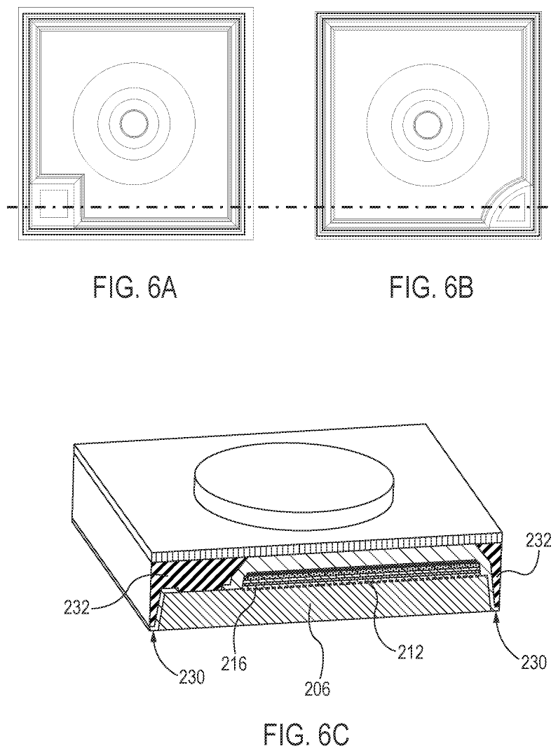

According to one or more embodiments, a LED pixel die is provided with regular (i.e., non self-aligned) n-contact formation at the pixel corners, for example as illustrated in FIGS. 6A-6C. Using the LED pixel die formed according to the present methods as described above in connection with FIGS. 5A-5F and 11, LED arrays can be provided having a variety of contact geometries. One embodiment of an LED array according to the present invention is illustrated in FIGS. 5F and 6A-6C.

According to one or more embodiments, an LED device 200 is provided in which an electrically conductive material 232 disposed in the trench (e.g., 218a, 218b) is separated from a hard mask layer 214, a P-contact layer 212, an n-type layer 204, an active layer 216, and a P-type layer 206 forming sidewalls of a mesa 210. According to one or more embodiments, a dielectric layer 230 extends between the semiconductor layers 203 and the electrically conductive material 232 along an increased length/surfaces of the trench (218a, 218b) and along the bottom surface 223 of the trench (218a, 218b). As such, the dielectric layer 230 optically isolates the trench 218a, 218b. This is in contrast with conventional designs illustrated, for example, in FIGS. 1-2 and as discussed further above.

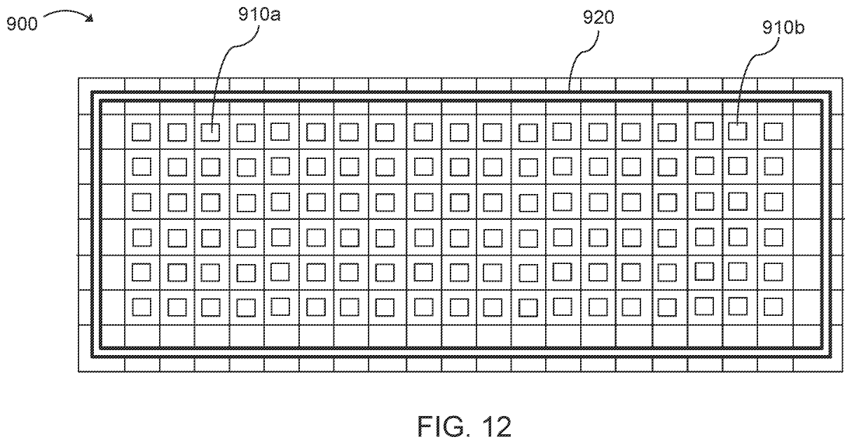

According to another embodiment, as illustrated in FIGS. 9A-91 and FIG. 11, a device 300 is provided having regular N-contact alignment with bottom dielectric coverage. FIG. 7A, operation 802 corresponds to the prior described embodiment at FIG. 3C operation 604. As such, according to one or more embodiments, prior to FIG. 7A, operation 802, each of FIGS. 3A-3B, operations 602-604 are carried out as set forth above. It is noted that various elements in FIGS. 3A-3K are numbered as device 100, p-type layers 104, n-type layers 106, etc., while corresponding elements in FIGS. 7A-71 are numbered as device 300, p-type layers 304, n-type layers 306, etc. All of the materials, methods, dimensions, and other details described in connection with the embodiment of FIGS. 3A-3K and 10 apply to the embodiment of FIGS. 7A-7H and 12.

With reference to FIG. 9A and FIG. 11, at operation 802, a spacer layer 324 is deposited on the sidewalls of the plurality of opening 308a, 308b. According to one or more embodiments, the spacer layer 324 is deposited along the entire height of the sidewalls. According to one or more embodiments, the spacer layer 324 can further be deposited on the top surface of the hard mask layer 314 and bottom surface 323 of the plurality of opening 308a, 308b. According to one or more embodiments, the spacer layer 324 is deposited along the entire length of the sidewalls 321, bottom surface 323, and the entire length of the top surface of the hard mask layer 314. According to one or more embodiments, the spacer layer 324 is substantially the same thickness along the entire length of the sidewalls. The spacer layer 324 may be formed using a conventional deposition technique, such as, for example, CVD, PECVD, ALD, evaporation, sputtering, chemical solution deposition, spin-on deposition, or other like processes. Deposition of the material that forms the spacer layer 324 can be done conformally, followed by etching to provide the spacer layer 324 only on the sidewalls 321, but not on the top surface of the hard mask layer 314 or on the bottom surface 323, thus providing the structure illustrated in FIG. 7A.

In one or more embodiments, the spacer layer 324 may comprise any suitable dielectric material known to the skilled artisan. In some embodiments, the spacer layer 324 comprises a dielectric material. In one or more embodiments, the spacer layer 324 comprises silicon oxide. In one or more embodiments, the spacer layer 324 has a thickness greater than about 10 nm, or greater than about 20 nm, or greater than about 100 nm. In other embodiments, the spacer layer 324 has a thickness in a range of from 10 nm to 500 nm.

Referring to FIG. 7B and FIG. 11, at operation 804, the plurality of openings 308a, 308b are further etched so that the openings 308a, 308b extend through the p-type layers 304, through the active region 316, and a depth into an upper portion of the n-type layers 306. In one or more embodiments, the extension of openings 308a, 308b at operation 804 may be carried out using a conventional directional etching process, such as dry etching. As illustrated in FIG. 7B, after operation 804, the openings 308a, 308b now include at least one sidewall 321 comprising a top sidewall portion formed by the spacer layer 224 and a bottom sidewall portion 326 comprising the p-type layers 304, active layer 316, and a portion of the n-type layers 306. The openings 308a, 308b further include a bottom surface 323 comprising a portion of the n-type layers 306. In one or more embodiments, a first opening 308a formed at operation 804 may have total a height (comprising the spacer layer 324 and the bottom sidewall portion 326) that is about the same as the height of a second opening 308b. In other embodiments, the first opening 308a may have a height that is different than the height of the second opening 308b. In one or more embodiments, the sidewalls of openings 308a, 308b formed at operation 804 may be completely vertical as illustrated in FIG. 7B or may have an angle of inclination up to 45 degrees.

Referring to FIG. 7C and FIG. 11, at operation 806, a dielectric layer 330 is deposited along the entire length of the sidewalls 321 of openings 308a, 308b formed at operation 804. According to one or more embodiments, for example as illustrated in FIG. 7C, the dielectric layer 330 is deposited so that it lines the sidewalls 321 of openings 308a and 308b (i.e., lines the sidewalls 321 which includes the surface of the spacer layer 324 and the bottom sidewall portion 326). According to one or more embodiments, the dielectric layer 330 is deposited so that it leaves the bottom surface 323 of openings 308a, 308b mostly exposed. For example, the dielectric layer 330 may be deposited to line the entire length of the sidewalls 321 which extends to the bottom surface 323 and, thus, provides an overlap on the bottom surface 323 corresponding to a thickness of the dielectric layer 330. In one or more embodiments, the dielectric layer 330 is deposited to line the bottom surface of openings 308a, 308b and the hard ask layer 314, followed by partial removal of the dielectric layer 330 (e.g., by etching) to provide the structure in FIG. 7C. The dielectric layer 330 formed at operation 806 may be formed using a conventional deposition technique, such as, for example, CVD, PECVD, ALD, evaporation, sputtering, chemical solution deposition, spin-on deposition, or other like processes.

In one or more embodiments, the dielectric layer 330 may comprise any suitable dielectric material known to the skilled artisan. As used herein, the term “dielectric” refers to an electrical insulator material that can be polarized by an applied electric field. In one or more embodiments, the dielectric layer 330 may comprise any suitable dielectric material known to the skilled artisan. In some embodiments, the dielectric layer 130 comprises a low-refractive index material. In some embodiments, the dielectric material comprises one of more of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ). While the term “silicon oxide” may be used to describe the dielectric layer 330, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. In one or more embodiments, the dielectric layer 330 comprises silicon oxide. In one or more embodiments, the dielectric layer 330 comprises the same material as the spacer layer 324 formed at operation 802.

Referring to FIG. 7D and FIG. 11, at operation 808, a photoresist 342 is deposited along the top surface 320 of the hard mask layer 314, the top surfaces of the spacer layer 324 and dielectric layer 310, and the dielectric layer 310 lining the sidewalls 321. Any conventional photoresist materials and deposition methods can suitably be used.

Referring to FIG. 7E and FIG. 11, at operation 810, the photoresist 342 is used as a mask and etching is carried out to form mesas 310 separated by trenches 318a, 381b extending through the entire depth of the n-type layers 306 to a surface of the substrate 302. In one or more embodiments, etching at operation 810 may be carried out using a conventional directional etching process, such as dry etching. As illustrated in FIG. 7E, upon removal of any residual photoresist 342, the trenches 318a, 318b formed by operation 810 include at least one sidewall comprising a top sidewall portion formed by the dielectric layer 330 deposited at operation 802 and a bottom sidewall portion 326 comprising a portion of the n-type layers 306. The trenches 318a, 318b further include a bottom surface 323 comprising a top surface of the substrate 302. In one or more embodiments, the trenches 318a, 318b formed at operation 810 include an upper wider portion 307a/307b disposed between the dielectric layer 330, and a bottom narrower portion 309a/309b disposed between the n-type layers 306.

Referring to FIG. 7F and FIG. 11, at operation 812, show formation of a dielectric layer 330 within the trenches 318a, 318b. According to one or more embodiments, for example as illustrated in FIG. 7F, the dielectric layer 330 lines the entire trench 318a (i.e., all surfaces of the upper wider portion 307a and bottom narrower portion 309a of trench 318a) including vertical sidewalls, the bottom surface 323 of trench 318a, and inwardly extending horizontal surface portions of the n-type layers 306 within the trench 318a. As further illustrated in FIG. 7F, the dielectric layer 330 can further line the vertical sidewalls of the upper wider portion 307b of trench 318b and portions of the inwardly extending horizontal surface portions 340 of the n-type layers 306 within the trench 318b. According to one or more embodiments, the dielectric layer 330 lines only the sidewalls of the upper wider portion 307b of trench 318b and a portion of the horizontal surface portions 340 adjacent the sidewalls of the upper wider portion 307b, while leaving exposed the surfaces of bottom narrower portion 309b of trench 318b and a portion of the horizontal surface 340 adjacent the bottom narrower portion 309b (e.g., as illustrated in FIG. 7F). In one or more embodiments, the dielectric layer 330 is deposited to line the entire trench 318b (horizontal surface portions 340 and the bottom surface 323 in trench 318b) and can further be deposited to line the hard mask layer 314, followed by partial removal of the dielectric layer 330 (e.g., by etching) to provide the structure in FIG. 7F.

Referring to FIG. 7G and FIG. 11, at operation 814, an electrically conductive material 332 is deposited. According to one or more embodiments, the electrically conductive material 332 is deposited to fill the trenches 318a, 318b and cover the exposed upper surfaces of the device 300. The electrically conductive material 332 can suitably be selected from any conventional electrically conductive materials such as, for example, electroplated copper (Cu).

Referring to FIG. 7H and FIG. 11, at operation 816, excess electrically conductive material 332 is removed (e.g., by planarizing) as discussed in connection with FIGS. 3J and 5E. As illustrated in the embodiment shown by FIG. 7H, the resulting upper surface of the device 300 includes the hard mask layer 314 surrounding the trenches 318a, 318b, upper surfaces of spacer layers 324, upper surfaces of the dielectric layer 330 lining the trenches 318a, 318b, and the planarized electrically conductive material 332 disposed within the trenches 318a, 318b.

Referring to FIGS. 71 and 11, at operations 818 and 820, a contact opening is formed in the hard mask layer 314 and a p-type contact material 336 (or an anode contact metal) is deposited in the contact opening. According to one or more embodiments, for example as illustrated in FIG. 7I, the contact opening is formed in the surface of the hard mask layer 314 between trenches 318a, 318b. The contact opening can be formed by etching. In one or more embodiments, the contact opening may be formed using a conventional directional etching process, such as dry etching. According to one or more embodiments, the p-type contact material 336 may comprise any suitable material known to the skilled artisan. In one or more embodiments, the p-type contact material 336 comprises a p-contact material selected from one or more of aluminum (Al), silver (Ag), gold (Au), platinum (Pt), and palladium (Pd). In specific embodiments, the p-type contact material 336 comprises silver (Ag). In some embodiments, additional metals may be added in small quantities to the p-type contact material 336 as adhesion promoters. Such adhesion promoters, include, but are not limited to, one or more of nickel (Ni), titanium (Ti), and chromium (Cr).

In later stages of processing, the entire device 300 or a piece of the device 300 is bonded to a system substrate such as a display backplane to form a system (e.g., FIG. 11, at operation 822). An array of landing pads may be arranged on the system substrate with dimensions aligned to those of the bonding pads on the device 300. The landing pads may be connecting to display driver circuitry in the system substrate. In one or more embodiments, after bonding, the substrate 302 is removed using a process such as laser lift-off if the substrate is a UV-transparent material such as sapphire.

According to one or more embodiments, a LED pixel die is provided with regular (i.e., non self-aligned) n-contact formation at the pixel corners, for example as illustrated in FIGS. 8A-8B. Using the LED pixel die formed according to the present methods as described above in connection with FIGS. 7A-71 and 12, LED arrays can be provided having a variety of contact geometries. One embodiment of an LED array according to the present invention is illustrated in FIGS. 71 and 8A-8B.

According to one or more embodiments, an LED device 300 is provided in which an electrically conductive material 332 disposed in the trench (e.g., 318a, 318b) is separated from semiconductor layers 303 (N-type layer 304, an active layer 316, and a P-type layer 306) forming sidewalls of a mesa 310. According to one or more embodiments, dielectric layer 330 extends between the semiconductor layers 302 and the electrically conductive material 332 along an increased length/surfaces of the trench (318a, 318b) and along at least a portion of the bottom surface 323 of the trench (318a, 318b). As such, the dielectric layer 330 optically isolates the trench 318a, 318b. This is in contrast with conventional designs illustrated, for example, in FIGS. 1-2 and as discussed further above.

According to embodiments of the disclosure, a pixel architecture is provided in which n-contact formation is at the mesa bottom over a limited region around the periphery of the pixel. The pixel architecture increases optical efficiency (PE and ExE) by significantly reducing absorption loss at pixel edges (trench area). According to various embodiments, the present disclosure makes it possible to optically isolate the trench region with a dielectric layer (including a distributed Bragg Reflector DBR). As used herein, a “distributed Bragg reflector” (DBR) refers to a structure (e.g. a mirror) formed from a multilayer stack of alternating thin film materials with varying refractive index, for example high-index and low-index films. In one or more embodiments, pair of films comprise silicon dioxide (SiO₂) and titanium dioxide (TiO₂) layers. In one or more embodiments, pair of films comprise silicon dioxide (SiO₂) and niobium pentoxide (NbO₅) layers.

According to some embodiments, n-contact formation is based on a self-alignment technique (e.g., as illustrated and described in connection with FIGS. 3A-3K and 12). Using the self-alignment technique, the dielectric layer generally does not cover a bottom surface of the trench. According to other embodiments not using self-alignment techniques, the dielectric layer covers at least a portion of the bottom surface of the trench (e.g., as illustrated and described in connection with FIGS. 5A-5F, 7A-71, and 10-12).

### Applications

LED devices disclosed herein may be monolithic arrays or matrixes. An LED device may be affixed to a backplane for use in a final application. Illumination arrays and lens systems may incorporate LED devices disclosed herein. Applications include but are not limited to beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. Light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting. Other applications include display devices.

### Display Devices

Some display devices comprise arrays and groups of LEDs or pixels, which include the embodiments disclosed herein.

FIG. 12 shows a top plan view of an LED monolithic array 900 comprising a plurality of pixels arranged in a grid of 6×19. Pixels 910a and 910b are examples. In this embodiment, a common cathode 920 is connected to the pixels. Anodes, not shown, present on the underside are included with each pixel. In one or more embodiments, the array comprises an arrangement of 2×2 mesas, 4×4 mesas, 20×20 mesas, 50×50 mesas, 100×100 mesas, or n1×n2 mesas, where each of n1 and n2 is a number in a range of from 2 to 1000, and n1 and n2 can be equal or not equal.

In one or more embodiments, arrays of LEDs (traditional, mini-LEDs, or uLEDs) are used. In one or more embodiments, micro-LEDs can support high density pixels having a lateral dimension less than 100 μm by 100 μm. In some embodiments, micro-LEDs with dimensions of about 50 μm in diameter or width and smaller can be used. Such micro-LEDs can be used for the manufacture of color displays by aligning in close proximity micro-LEDs comprising red, blue and green wavelengths. Such micro-LEDs can be used for the manufacture of monochrome displays, such as those for automotive lighting arrangements.

In some embodiments, the light emitting arrays include small numbers of LEDs positioned on substrates that are centimeter scale area or greater. In some embodiments, the light emitting arrays include micro-LED pixel arrays with hundreds, thousands, or millions of light emitting LEDs positioned together on centimeter scale area substrates or smaller. In some embodiments, LEDs can include light emitting diodes sized between 1 microns and 500 microns. The light emitting array(s) can be monochromatic, RGB, or other desired chromaticity. In some embodiments, pixels can be square, rectangular, hexagonal, or have curved perimeter. Pixels can be of the same size, of differing sizes, or similarly sized and grouped to present larger effective pixel size.

In some embodiments, light emitting pixels and circuitry supporting light emitting arrays are packaged and optionally include a submount or printed circuit board connected for powering and controlling light production by semiconductor LEDs. In certain embodiments, a printed circuit board supporting light emitting array includes electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the light emitting array and a power supply, and also provide heat sink functionality.

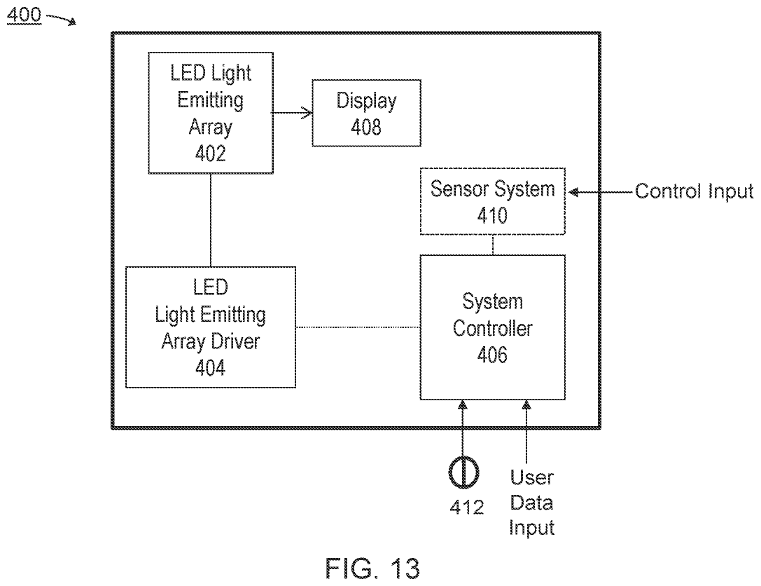

FIG. 13 schematically illustrates an exemplary display system 400 utilizing LEDs disclosed herein. The display system 400 comprises an LED light emitting array 402 and display 408 in electrical communication with an LED driver 404. The display system 400 also comprises a system controller 406, such as a microprocessor. The controller 406 is coupled to the LED driver 404. The controller 406 may also be coupled to the display 408 and to optional sensor(s) 410, and be powered by power source 412. In one or more embodiments, user data input is provided to system controller 406.

Optionally sensors 410 with control input may include, for example, positional sensors (e.g., a gyroscope and/or accelerometer) and/or other sensors that may be used to determine the position, speed, and orientation of system. The signals from the sensors 410 may be supplied to the controller 406 to be used to determine the appropriate course of action of the controller 406 (e.g., which LEDs are currently illuminating a target and which LEDs will be illuminating the target a predetermined amount of time later).

In operation, illumination from some or all of the pixels of the LED array in 402 may be adjusted-deactivated, operated at full intensity, or operated at an intermediate intensity. As noted above, beam focus or steering of light emitted by the LED array can be performed electronically by activating one or more subsets of the pixels, to permit dynamic adjustment of the beam shape without moving optics or changing the focus of the lens in the lighting apparatus.

Other applications of LED arrays and devices herein include visualization systems, such as virtual reality systems and augmented reality systems and an augmented reality/virtual reality (AR/VR) systems, which may utilize any of the LEDs, including uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

According to one or more embodiments, a visualization system can include one or more light sources that can provide light for a display of the visualization system. Suitable light sources can include a light-emitting diode according to the present disclosure, a monolithic light-emitting diode according to the present disclosure, a plurality of light-emitting diodes according to the present disclosure, an array of light-emitting diodes according to the present disclosure, an array of light-emitting diodes according to the present disclosure disposed on a common substrate, a segmented light-emitting diode according to the present disclosure that is disposed on a single substrate and has light-emitting diode elements that are individually addressable and controllable (and/or controllable in groups and/or subsets), an array of micro-light-emitting diodes (microLEDs) according to the present disclosure, and others.

According to one or more embodiments, a light-emitting diode (LED) can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that has a wavelength greater than a wavelength of the excitation light.

According to one or more embodiments, the light-emitting diode (LED) can include light-emitting diodes that emit different colors or wavelengths including, for example, red light-emitting diodes that can emit red light, a green light-emitting diodes that can emit green light, and a blue light-emitting diodes that can emit blue right. A light source can be provided that includes a red light-emitting diode, a green light-emitting diode, and a blue light-emitting diode such that the red, green, and blue light combine in specified ratios to produce any suitable color that is visually perceptible in a visible portion of the electromagnetic spectrum.

According to one or more embodiments, one or more LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. According to one or more embodiments, phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. According to one or more embodiments, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

As used herein, the term “phosphor” refers to a solid material which emits visible light when exposed to radiation from a deep blue, ultra-violet, or electron beam source. Through careful tuning of the phosphor composition and structure, the spectral content of the emitted light can be tailored to meet certain performance criteria. In some embodiments, the phosphor is selected from a ceramic phosphor plate or phosphor in silicone.

According to one or more embodiments, one or more individual pcLEDs comprise a light emitting semiconductor diode (LED) structure disposed on a substrate, and a phosphor layer (not shown) disposed on the LED. The light emitting semiconductor diode structure generally comprises an active region disposed between n-type and p-type layers. Application of a suitable forward bias across the diode structure results in emission of light from the active region. The wavelength of the emitted light is determined by the composition and structure of the active region. The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials. Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate. In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light. The individual LEDs or pcLEDs in an array may be individually operable (addressable) and/or may be operable as part of a group or subset of (e.g., adjacent) LEDs or pcLEDs in the array. Another aspect of the disclosure pertains to an electronics system. In one or more embodiments, an electronic system comprises the LED monolithic devices and arrays described herein, and driver circuitry configured to provide independent voltages to one or more of p-contact layers. In one or more embodiments, the electronic system is selected from the group consisting of a LED-based luminaire, a light emitting strip, a light emitting sheet, an optical display, and a microLED display.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,” “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light emitting diode (LED) device comprising:
at least one mesa comprising semiconductor layers, the semiconductor layers including an n-type layer, an active layer, and a p-type layer, the at least one mesa having a top surface and sidewalls, at least one sidewall defining a trench having a bottom surface;
a dielectric layer disposed on at least portions of the sidewalls;
an electrically conductive material disposed in the trench and in contact with the dielectric layer; and
a p-type contact on the top surface of the mesa,
wherein the dielectric layer extends between the semiconductor layers and the electrically conductive material along at least a portion of the trench opposing sidewalls,
wherein at least a portion of the electrically conductive material is in direct contact with at least a portion of the bottom surface of the trench and/or at least a portion of the n-type layer, and
wherein the dielectric layer optically isolates the trench.

2. The LED device of claim 1, wherein the dielectric layer is further disposed on at least a portion of the bottom surface of the trench.

3. The LED device of claim 1, wherein the trench includes a lower narrower portion and an upper wider portion, the upper wider portion comprising opposing sidewalls and opposing horizontal surfaces, and at least a portion of the electrically conductive material is in direct contact with at least a portion of the opposing horizontal surfaces.

4. The LED device of claim 3, wherein the dielectric layer is further disposed along an entire length of the bottom surface of the trench.

5. The LED device of claim 3, wherein at least a portion of the electrically conductive material is in direct contact with at least a portion of the bottom surface of the trench.

6. The LED device of claim 1, wherein the dielectric layer comprises a material selected from the group consisting of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ).

7. The LED device of claim 6, wherein the dielectric layer comprises silicon oxide.

8. The LED device of claim 6, wherein the dielectric layer has a thickness of at least about 0.2 microns.

9. The LED device of claim 1, wherein the electrically conductive material comprises one or more of silver (Ag) and aluminum (Al).

10. The LED device of claim 1, further comprising a light converting phosphor layer.

11. The LED device of claim 1, wherein the mesa further comprises a P-contact layer.

12. A light emitting diode (LED) array comprising:
a plurality of mesas defining pixels, each of the mesas comprising semiconductor layers, the semiconductor layers including an n-type layer, an active layer, and a p-type layer, each of the mesas having a top surface and sidewalls;
a plurality of trenches, each of the trenches disposed between each of the mesas, each of the trenches having a bottom surface and opposing side surfaces defining the sidewalls of the mesas, at least one trench having a lower narrower portion and an upper wider portion, the upper wider portion further comprising opposing horizontal surfaces;
an electrically conductive material disposed in each of the trenches;
a dielectric layer disposed on at least portions of the sidewalls;
an electrically conductive material disposed in the trench and in contact with the dielectric layer; and
a p-type contact on the top surface of at least one mesa,
wherein at least a portion of the electrically conductive material is in direct contact with at least a portion of the bottom surface of at least one trench and/or at least a portion of the n-type layer in at least one trench, and
wherein the dielectric layer optically isolates the trenches.

13. The LED device of claim 12, wherein the dielectric layer is further disposed on at least a portion of the bottom surface of at least one trench.

14. The LED device of claim 12, wherein at least a portion of the electrically conductive material is in direct contact with at least a portion of the opposing horizontal surfaces.

15. The LED device of claim 14, wherein the dielectric layer is further disposed along an entire length of the bottom surface of at least one trench.

16. The LED device of claim 14, wherein at least a portion of the electrically conductive material is in direct contact with at least a portion of the bottom surface of at least one trench.

17. A display comprising: the light emitting diode (LED) array according to claim 12 affixed to a device substrate by anode metallization bumps.

18. The display of claim 17, wherein the pixels emit a single color.

19. The display of claim 18, wherein a first plurality of pixels is designed to emit a red color, a second plurality of pixels is designed to emit a blue color, and a third plurality of pixels is designed to emit a green color.
